(19) United States
(12) Patent Application Publication
(10) Pub. No.: US 2023/0360948 A1
(43) Pub. Date: Nov. 9, 2023

(54) HIGH-PRECISION PRINTED STRUCTURES AND METHODS OF MAKING

(71) Applicant: X-Celeprint Limited, Dublin (IE)

(72) Inventors: Ruggero Loi, Selargius (IT); Ronald S. Cok, Rochester, NY (US)

(21) Appl. No.: 17/955,346

(22) Filed: Sep. 28, 2022

Related U.S. Application Data
(60) Provisional application No. 63/339,934, filed on May 9, 2022.

(51) Int. Cl. H01L 21/683; H01L 21/76; H01L 21/56

(52) U.S. Cl. CPC H01L 21/6836; H01L 21/76; H01L 21/561; H01L 2221/68327; H01L 2221/68381

(57) ABSTRACT

A printed structure includes a target substrate and structures extending from a surface of the target substrate and a component disposed on the surface in alignment with the structures. The structures can be spatially separated independent structures. The component is non-native to the target substrate and can comprises a component substrate separate and independent from the target substrate. The component can be micro-transfer printed to the target substrate and can comprise a broken, fractured, or separated tether.

### PRIORITY APPLICATION

This application claims the benefit of U.S. Patent Application No. 63/339,934 filed May 9, 2022 entitled High-Precision Structures and Methods of Making, the content of which is hereby incorporated by reference in its entirety.

### CROSS REFERENCE TO RELATED APPLICATION

Reference is made to U.S. patent application Ser. No. 16/186,173 filed Nov. 9, 2018 entitled “Interconnection by Lateral Printing” by Meitl et al., the disclosure of which is incorporated by reference herein in its entirety.

### TECHNICAL FIELD

The present disclosure relates to printing components from a source wafer to a destination substrate with improved alignment accuracy using a transfer element, such as a stamp.

### BACKGROUND

Substrates with electronically active components distributed over the extent of the substrate may be used in a variety of electronic systems, for example, in flat-panel display devices such as flat-panel liquid crystal or organic light emitting diode (OLED) displays, in imaging sensors, and in flat-panel solar cells. The electronically active components are typically either assembled on the substrate, for example using individually packaged surface-mount integrated-circuit devices and pick-and-place tools, or by depositing (e.g., sputtering or spin coating) a layer of semiconductor material on the substrate and then photolithographically processing the semiconductor material to form thin-film circuits on the substrate. Individually packaged integrated-circuit devices typically have smaller transistors with higher performance than thin-film circuits but the packages are larger than can be desired for highly integrated systems.

Other methods for transferring active components from one substrate to another are described in U.S. Pat. No. 7,943,491. In an example of these approaches, small integrated circuits are formed on a native semiconductor source wafer. The small unpackaged integrated circuits, or chiplets, are released from the native source wafer by etching a layer formed beneath the circuits. A viscoelastic stamp is pressed against the native source wafer and the process side of the chiplets is adhered to individual stamp posts. The chiplets on the stamp are then pressed against a destination substrate or backplane with the stamp and adhered to the destination substrate. In another example, U.S. Pat. No. 8,722,458 entitled Optical Systems Fabricated by Printing-Based Assembly teaches transferring light-emitting, light-sensing, or light-collecting semiconductor elements from a wafer substrate to a destination substrate or backplane. In certain applications, it can be important for transferred components to be located precisely and accurately on a destination substrate or backplane. When components are accurately located, they can be positioned closer together to form denser and smaller systems with improved performance. In particular, printed devices can be more accurately positioned with each other or with respect to photolithographically defined wires. For example, accurately positioned opto-electronic devices experience fewer conversion or connection losses. There is a need, therefore, for methods, devices, and structures to enable precise and accurate printing of components.

### SUMMARY

The present disclosure provides, inter alia, structures, materials, and methods that enable precise and accurate printing (e.g., micro-transfer printing) of components from a native source wafer to a non-native target substrate in alignment with structures disposed on the target substrate.

According to some embodiments of the present disclosure, a method of making a printed structure (e.g., a micro-transfer printed structure) comprises providing a target substrate and a structure protruding from a surface of the target substrate, providing a transfer element and a component adhered to the transfer element (e.g., wherein the component comprises a component substrate that is separate and independent from the target substrate), moving the transfer element with the adhered component vertically toward the surface of the target substrate and horizontally towards the structure at least until the component physically contacts the structure or is adhered to the surface of the target substrate, and separating the transfer element from the component. The transfer element can be a viscoelastic stamp. Thus, in embodiments the component is non-native to the target substrate. In some embodiments, the structure is formed on and native to the target substrate. In some embodiments, the structure is non-native to the target substrate, for example transferred to the target substrate from a structure source wafer.

Some methods of the present disclosure comprise moving the transfer element toward the target substrate after the component physically contacts the structure or is adhered to the surface of the target substrate and before the transfer element is separated from the component in order to press the component toward the target substrate. Some methods of the present disclosure comprise moving the transfer element toward the target substrate after the transfer element is separated from the component to press the component toward the target substrate.

According to some embodiments, the component physically contacts the structure while the component is above and not in contact with the surface of the target substrate. According to some embodiments, the component physically contacts the structure while the component is in contact with the surface of the target substrate. Some methods of the present disclosure comprise moving the transfer element vertically away from the target substrate and horizontally toward the structure after the component physically contacts the structure.

According to some embodiments of the present disclosure, a printed structure (e.g., a micro-transfer-printed structure) comprises a target substrate and one or more structures protruding from a surface of the target substrate and a component in alignment with at least one of the structures. The component can comprise a component substrate separate and independent from the target substrate. According to some embodiments, the component is disposed on the surface of the target substrate within one micron (e.g., within 1.0 micron, within 0.75 microns, within 0.5 microns, within 0.25 microns, or within 0.1 microns) of a structure. In some embodiments, the component is disposed on the surface of the target substrate within five microns (e.g., within two microns) of a structure. The component can comprise a broken or separated tether. The component can be in contact with a structure. A structure can comprise a broken or separated tether.

The component can be disposed on the surface of the target substrate laterally adjacent to the structure. The structure can have a structure edge and the component can be disposed adjacent to the structure edge and within a micron of all of the edge (e.g., within a micron of the bottom of the structure and structure edge adjacent to the target substrate or within a micron of the top of the structure and the structure edge on a side of the structure opposite the target substrate. In embodiments, the component is not disposed on the structure, for example not on a top side of the structure opposite the target substrate.

According to some embodiments of the present disclosure, the component and the structure are aligned optical elements. For example, the structure comprises a waveguide, such as a light pipe, light conductor, or fiber optic element. The component, the structure, or both the component and the structure can comprise one or more of a laser, an optical amplifier, an optical modulator, a light-emitting diode, a light sensor such as a photosensor (e.g., photodiode), and an optical fiber. According to embodiments of the present disclosure, the printed structure is a photonic system, a photonic integrated structure, or a silicon photonic structure. The target substrate can be a silicon substrate comprising integrated circuitry that is electrically connected to the component.

According to some embodiments of the present disclosure, the component has a length or a width or a length and a width less than or equal to 200 microns, less than or equal to 100 microns, less than or equal to 50 microns, less than or equal to 20 microns, less than or equal to 10 microns, less than or equal to 5 microns, less than or equal to 3 microns, less than or equal to 2 microns, or less than or equal to one micron.

In some configurations of the present disclosure, (i) the structure has a flat face adjacent to the component, (ii) the component has a substantially flat face adjacent to the structure, or (iii) both (i) and (ii). According to some embodiments, the structure has a non-planar face adjacent to the component and the component has a non-planar face complementary to the non-planar face of the structure. In some embodiments, at least a portion of the non-planar face of the structure is in contact with the non-planar face of the component.

According to some embodiments of the present disclosure, an adhesive is disposed on the surface of the target substrate. The adhesive can adhere the component to the target substrate. The adhesive can be disposed at least partially between the structure and the component.

According to some embodiments of the present disclosure, the structure, the component, or both the structure and the component are operable to receive or emit light. For example, both the structure and the component can comprise a light pipe and the light pipe in the structure can be in alignment with the light pipe in the component. In some embodiments, the structure comprises a light pipe and the component comprises a light emitter or light sensor in alignment with the light pipe in the structure. In some embodiments, the component comprises a light pipe and the structure comprises a light emitter or light sensor in alignment with the light pipe in the component.

According to some embodiments of the present disclosure, the component is disposed and operable to emit light to or receive light from the substrate, the structure is disposed and operable to emit light to or receive light from the substrate, or the component is disposed and operable to emit light to or receive light from the structure.

According to some embodiments of the present disclosure, the printed structure comprises a controller disposed on the surface of the substrate. The controller can be electrically connected to the component and operable to control operation of the component or the controller can be electrically connected to the structure and operable to control operation of the structure, or both.

According to some embodiments of the present disclosure, the printed structure comprises an encapsulation layer disposed at least partly over one or more of the component, the structure, and any gap between the component and the structure. The encapsulation layer can comprise or can be coated with a patterned or unpatterned light-reflective layer.

According to some embodiments, the component has a thickness equal to or greater than a thickness of the structure. The component can comprise a component material, the target substrate can comprise a substrate material, and the component material can be substantially different from the substrate material.

According to some embodiments of the present disclosure, the printed structure comprises a reflective material disposed (i) between the component and the target substrate, (ii) between the structure and the target substrate, or (iii) both (i) and (ii).

The component can be a first component and the printed structure can comprise a second component disposed on the surface of the target substrate within one micron (e.g., within 1.0 micron, within 0.75 microns, within 0.5 microns, within 0.25 microns, or within 0.1 microns) of the first component and the second component comprises a broken or separated tether.

The structure can comprise two or more structure faces, the component can comprise two or more component faces, and the component can be disposed on the surface of the target substrate so that at least one structure face is within one micron (e.g., within 1.0 micron, within 0.75 microns, within 0.5 microns, within 0.25 microns, or within 0.1 microns) of a component face.

The structure can comprise or have a structure face and the component can comprise or have a component face opposed or adjacent to the structure face. The structure face can comprise an indentation and the component face comprises a protrusion complementary to the indentation, for example complementary in shape, in size, or in both shape and size. The structure face can comprise a protrusion and the component face can comprise an indentation complementary to the protrusion, for example complementary in shape, in size, or in both shape and size. A protrusion can fit into an indentation, for example when complementary in shape, in size, or in both shape and size.

According to some embodiments, the component comprises connection posts. The connection posts can be sharp, can comprise a sharp point or can have a distal end with a smaller area than a base area. The connection posts can be electrically conductive and can electrically connect to an electrically active circuit or structure in the component.

According to some embodiments of the present disclosure, a printed structure comprises a target substrate and structures extending from a surface of the target substrate. The structures can be spatially separated independent structures. A component can be disposed on the surface in alignment with the structures. The component can be non-native to the target substrate (e.g., the component comprises a component substrate separate and independent from the target substrate). The component can be micro-transfer printed from a component source wafer to the surface of the target substrate and can, in consequence, comprise a broken (e.g., fractured) or separated tether.

The component can be disposed on the surface of the target substrate within one micron (e.g., within 1.0 micron, within 0.75 microns, within 0.5 microns, within 0.25 microns, or within 0.1 microns) of at least one of the structures, of two or more of the structures, or of all of the structures.

A cavity can be disposed (e.g., formed by etching) within the target substrate, (e.g., etched into the surface of the target substrate). The cavity can comprise a cavity bottom (e.g., a floor) and cavity walls. The surface of the target substrate can be the cavity bottom, and at least one of the structures can comprise one of the cavity walls.

Multiple non-native components (e.g., each comprising component substrates separate and independent from the target substrate) can be disposed in the cavity in alignment with groups of structures on the surface.

In embodiments of the present disclosure, at least one of the structures is (e.g., some or all of the structures are) native to the target substrate (e.g., are grown on the target substrate or have been formed by etching into the target substrate). At least one of the structures or all of the structures can be defined by a patterned etching into the target substrate, for example in a common patterning and etching step. Each of one or more of the structures can be an island of the target substrate extending from the surface, for example where the surface is a cavity bottom. At least one, some, or all of the structures can be non-native to the target substrate, for example has been printed to the target substrate using micro-transfer printing and can comprise a broken (e.g., fractured) or separated tether). At least one, some, or all of the structures can be adhered to the target substrate by adhesive. At least one of the structures can be disposed in a cavity in which the component is also disposed. In some embodiment, the printed structure comprises a broken (e.g., fractured) or separated tether as a consequence of micro-transfer printing the printed structure from a source wafer to a target substrate.

According to embodiments of the present disclosure, each structure of two or more of the structures has a structure edge and the structure edges of the two or more of the structures are in a substantially straight line parallel to the surface of the target substrate. In some embodiments, the component has one or more component edges and at least one or more of the component edges is substantially parallel to at least one of the structure edges of the two or more of the structures. In some embodiments, each structure of two or more of the structures has a structure edge and the structure edges are disposed at an angle of substantially ninety degrees parallel to the surface of the target substrate. In some embodiments, each structure of two or more of the structures has a structure edge and the structure edges are disposed at an angle less than ninety degrees parallel to the surface of the target substrate or at an angle greater than ninety degrees parallel to the surface of the target substrate.

According to some embodiments, the component has two component edges and each structure of two or more of the structures has a structure edge and each component edge is disposed substantially parallel to the structure edge of one of the two or more of the structures. The two component edges can be component ends. In some embodiments, the two component edges are not parallel. In some embodiments, the two component edges are parallel.

In some embodiments, the structures comprise a first structure and a second structure, the component has a first component end and a second component end, and the first structure is disposed closer to the first component end than to the second component end and the second structure is disposed closer to the second component end than to the first component end. The structures can comprise a first structure having a first structure edge and a second structure having a second structure edge, the component has a first component end having a first component edge and an opposing second component end having a second component edge, the first structure edge is at a non-orthogonal angle with respect to the second structure edge in a direction parallel to the surface, and the first component edge is substantially parallel to the first structure edge and the second component edge is substantially parallel to the second structure edge.

According to embodiments of the present disclosure, a printed structure comprises a target substrate and one or more substrate structures extending from a surface of the target substrate. A component non-native to the target substrate can be disposed on the surface in alignment with the one or more substrate structures. The component can comprise a component substrate separate and independent from the target substrate and can comprise a broken (e.g., fractured) or separated tether. The component can comprise one or more component structures each extending from a (e.g., a portion of a common) side (e.g., edge or face) of the component. The one or more component structures can each be in contact with or within one micron of the one or more substrate structures. The one or more component structures can be two or more spatially separated component structures, for example extending from a common side (e.g., edge or face) or a portion of a common side of the component.

In some embodiments, the target substrate comprises a cavity having a cavity bottom and cavity walls disposed within the target substrate. The surface of the target substrate can be the cavity bottom and at least one of the substrate structures can comprise or be one of the cavity walls.

In some embodiments, the one or more component structures (e.g., two component structures) can protrude farther from a side of the component than the broken or separated tether. The broken or separated tether can be disposed between two component structures on a common side, face, or edge of the component.

In some embodiments, the printed structure comprises an adhesive disposed on the target substrate and wherein the component is disposed on the adhesive.

In some embodiment, the component has a longer side and a shorter side and the component can be adjacent to more structures on the longer side than on the shorter side. The longer side can extend in a length direction parallel to the surface and can extend a distance that is a length of the component. The shorter side can extend in a width direction parallel to the surface and can extend a distance that is a width of the component.

The component can be a photonic or electro-optic device such as a laser, an optical amplifier, an optical modulator, or a light sensor. At least one of the structures can comprise a waveguide. The waveguide can provide or receive light to or from the component and can be optically aligned with the component. In some embodiments, the printed structure is a photonic device

In some embodiments, the component protrudes above at least one of the structures. In some embodiments, a top surface of the component and a top surface of at least one of the structures reside in a common plane. In some embodiments, the component has a height, each of the structures extends above the target substrate by at least a minimum distance, and the height of the component is at least as large as the minimum distance. In some embodiments, one or more structures are disposed on a first side of a component and one or more structures are disposed on a second side of the component different from the first side (e.g., opposite or adjacent to the first side) [e.g., wherein each of the one or more structures disposed on the first side comprises an optical element (e.g., a waveguide, an optical amplifier, or an optical modulator) and the one or more structures disposed on the second side do not comprise an optical element].

In some embodiments, the component comprises a broken or separated tether that is disposed laterally between ones of the structures.

In some embodiments, each of the structures comprises an edge and the component is disposed adjacent to the structures such that a gap exists between each of the edges and the component. The gap can be no more than one micron between each of the edges and the component. In some embodiments, the component has a cut-off corner that defines the gap between the component and each of the edges.

In some embodiments, an adhesive is disposed on the target substrate and the component is disposed on the adhesive so that at least some of the adhesive is disposed between the component and the surface of the target substrate and adheres the component to the target substrate. At least some of the adhesive can be disposed laterally between the structures and at least some of the adhesive can be disposed laterally between a structure and the component. A thickness of the adhesive in the gap can be greater than a thickness of the adhesive between the component and the surface of the target substrate. A thickness of the adhesive in the gap can be greater than a thickness of the adhesive between the edges of two or more of the structures.

According to some embodiments, a printed structure comprises a gutter (a trench), or multiple separate gutters (multiple separate trenches), formed in the target substrate and disposed between the component and at least one of the structures, beneath the component, or both between the component and at least one of the structures and beneath the component. Where multiple gutters are present, in some embodiments some or all of the gutters can be connected. In some embodiments, some or all of the gutters are disconnected from any other of the gutters. The gutter can be at least partially filled with the adhesive. In some embodiments, the gutter has a depth no less than 500 nm (e.g., no less than one micron, no less than two microns, or no less than three microns). In some embodiments, the gutter has a depth no less than a thickness of the adhesive between the component and the surface (e.g., a depth no less than twice the thickness of the adhesive between the component and the surface, a depth no less than five times the thickness of the adhesive between the component and the surface, a depth no less than ten times the thickness of the adhesive between the component and the surface, a depth no less than twenty times the thickness of the adhesive between the component and the surface, a depth no less than fifty times the thickness of the adhesive between the component and the surface, or a depth no less than one hundred times the thickness of the adhesive between the component and the surface).

In embodiments according to the present disclosure, a printed structure can comprise a target substrate. A component can be disposed on the surface of the target substrate. The component can be non-native to the target substrate, for example the component can comprise a component substrate separate and independent from the target substrate. The component can comprise a broken (e.g., fractured) or separated tether as a consequence of micro-transfer printing the component from a component source wafer to the surface of the target substrate. In some embodiments, a structure extends from a surface of the target substrate and the component is disposed in alignment with the structure. The structure can be native or non-native to the target substrate.

A gutter can be formed in the target substrate and disposed laterally adjacent to the component or beneath the component, or both. The gutter can be disposed laterally between the component and the structure. The gutter can be disposed within five microns (e.g., within three microns, within two microns, within one micron, within 1.0 micron, within 0.75 microns, within 0.5 microns, within 0.25 microns, or within 0.1 microns) of the component. In some embodiments, the gutter has a depth no less than 500 nm (e.g., no less than one micron, no less than two microns, or no less than three microns) In some embodiments, the gutter has a depth no less than a thickness of the adhesive between the component and the surface (e.g., a depth no less than twice the thickness of the adhesive between the component and the surface, a depth no less than five times the thickness of the adhesive between the component and the surface, a depth no less than ten times the thickness of the adhesive between the component and the surface, a depth no less than twenty times the thickness of the adhesive between the component and the surface, a depth no less than fifty times the thickness of the adhesive between the component and the surface, or a depth no less than one hundred times the thickness of the adhesive between the component and the surface).

Some embodiments of the present disclosure comprise an adhesive that adheres the component to the target substrate and the gutter is at least partially filled with the adhesive. The adhesive can be disposed between the component and the surface of the target substrate.

In some embodiments, a printed structure comprises a target substrate having a substrate surface, a gutter disposed in the target substrate, an adhesive disposed on the target substrate and at least partially in the gutter, and a component printed onto the substrate surface adjacent to or at least partially over the gutter. The component can comprise a broken (e.g., fractured) or separated tether as a consequence of transfer printing from a component source wafer to the target substrate. In some embodiments, the printed structure comprises a substrate structure extending from the substrate surface adjacent to the gutter. In some embodiments, the gutter is at least partially laterally between the printed component and the substrate structure. In some embodiments, the printed component is in contact with the substrate structure and the gutter is beneath the component (e.g., in a direction toward the target substrate from the component).

The component can be disposed on the surface of the target substrate within one micron (e.g., within 1.0 micron, within 0.75 microns, within 0.5 microns, within 0.25 microns, or within 0.1 microns) of the structure. The component can be a photonic device such as a laser, an optical amplifier, an optical modulator, or a light sensor. At least one of the structures comprises a waveguide (e.g., that is optically aligned with the laser, the optical amplifier, the optical modulator, or the light sensor). The printed structure is a photonic device, a photonic structure, or a photonic system.

According to embodiments of the present disclosure, a method of making a printed structure comprises providing a target substrate and two or more structures extending from a surface of the target substrate (e.g., wherein the structures are spatially separated independent structures), providing an adhesive on the surface of the target substrate, providing a transfer element and a component adhered to the transfer element (e.g., wherein the component comprises a component substrate that is separate and independent from the target substrate), moving the transfer element with the adhered component vertically toward the surface of the target substrate and horizontally towards at least one of the structures at least until the component physically contacts a structure of the at least one of the structures or is adhered to the surface of the target substrate, thereby pushing at least a portion of the adhesive with the component, and separating the transfer element from the component, thereby printing the component to the target substrate. The step of moving the transfer element can comprise pushing the adhesive with the component, for example pushing the adhesive laterally along the surface of the target substrate, for example toward a structure, and piling up the adhesive on the surface between the component and the structure.

Thus, in some embodiments, the structures comprise two or more spatially separated independent structures protruding from the surface of the target substrate and the method comprises pushing the portion of the adhesive laterally into a gap between the two structures or toward the two structures. In some embodiments, the two or more structures comprise structure edges forming an angle defined by lines extending along the structure edges parallel to a surface of the target substrate and the method comprises pushing the portion of the adhesive between the structures toward an intersection of the lines (e.g., into or toward a corner). The two or more spatially separated structures can be separated by a separation distance and the transfer element can move the adhered component horizontally towards one of the structures a shear distance, and the shear distance can be less than the separation distance in a direction separating the structures. The structure can comprise edges forming an angle defined by lines extending along the edges parallel to a surface of the target substrate, the component has a cut-off corner forming the gap between the component and an intersection of the lines and comprising pushing the portion of the adhesive toward the intersection. The target substrate can comprise a gutter disposed between the structure and the component and methods of the present disclosure can comprise pushing the portion of the adhesive into the gutter. Methods of the present disclosure can comprise moving the component horizontally towards one of the structures after the component is in contact with the adhesive or the target substrate. The component can be disposed on the surface of the target substrate within one micron (e.g., within 1.0 micron, within 0.75 microns, within 0.5 microns, within 0.25 microns, or within 0.1 microns) of or in contact with at least one of the structures, of two or more of the structures, or of all of the structures after the transfer element is separated from the component.

In some embodiments, the component has two component edges at component ends, each of two of the structures has a structure edge, the two component edges are not parallel, and the method comprises moving the component with the transfer element until each of the two component edges is disposed substantially parallel to the structure edge of one of the two of the structures. In some embodiments, each of the two component edges are disposed on the surface of the target substrate a distance of no greater than one micron from the structure edge of the one of the two of the structures.

According to embodiments of the present disclosure, a method of making a printed structure comprises providing a target substrate and one or more structures extending from a surface of the target substrate and a gutter in the target substrate that is adjacent to at least one structure of the one or more structures, providing an adhesive on the surface of the target substrate, providing a transfer element and a component adhered to the transfer element (e.g., wherein the component comprises a component substrate that is separate and independent from the target substrate), moving the transfer element with the adhered component vertically toward the surface of the target substrate and horizontally towards a structure of the one or more structures at least until the component physically contacts the structure or is adhered to the surface of the target substrate, thereby pushing at least a portion of the adhesive with the component into the gutter such that the gutter becomes at least partially filled with the adhesive, and separating the transfer element from the component.

According to embodiments of the present disclosure, a method of making a printed structure comprises providing a target substrate and two structures extending from a surface of the target substrate, wherein each of the two structures has a structure edge and the two structure edges define two lines parallel to the surface that are not parallel, providing a transfer element and a component adhered to the transfer element, wherein the component comprises two component edges at component ends that are not parallel (e.g., and comprises a component substrate that is separate and independent from the target substrate), moving the transfer element with the adhered component vertically toward the surface of the target substrate and horizontally towards both of the two structures at least until (i) each of the two component edges is disposed substantially parallel to the of one a structure edge of one of the two structures and (ii) each of the component edges physically contacts one of the structures or is adhered to the surface of the target substrate, and separating the transfer element from the component.

According to embodiments of the present disclosure, a method of making a printed structure comprises providing a target substrate comprising a gutter formed in the target substrate and adhesive disposed on the target substrate adjacent to the gutter and printing a component to a target substrate by moving the component vertically towards the target substrate and horizontally over the target substrate such that the component becomes adhered to the target substrate with the adhesive, wherein the gutter becomes at least partially filled with the adhesive during the printing (e.g., due to the component pushing the adhesive as the component is printed). Methods can comprise providing a structure disposed on the target substrate (e.g., native or non-native to the target substrate), wherein printing the component comprises printing the component in alignment with the structure. The component can be an opto-electronic component and the structure can comprise a waveguide and printing the component can comprise aligning the component with the waveguide. In some embodiments, no adhesive is disposed in an optical path between the optoelectronic component and the waveguide after the printing. In some embodiments, the printing of the component comprises moving a transfer element on which the component is adhered and separating the transfer element from the component after the component is adhered to the target substrate with the adhesive. In some embodiments, the printed structure comprises the component, the adhesive, and the target substrate.

Some embodiments of the present disclosure provide methods, devices, and structures that enable precise and accurate micro-transfer printing components from a native source wafer to a non-native destination substrate. The components can be aligned with the structures and can be optical components.

### BRIEF DESCRIPTION OF THE DRAWINGS

The foregoing and other objects, aspects, features, and advantages of the present disclosure will become more apparent and better understood by referring to the following description taken in conjunction with the accompanying drawings, in which:

FIG. 1 is a flow diagram of methods according to illustrative embodiments of the present disclosure;

FIGS. 2A-2I are successive cross sections of structures as described in the flow diagrams of FIGS. 1, 3A, and 3B according to illustrative embodiments of the present disclosure;

FIGS. 3A and 3B are flow diagrams of methods according to illustrative embodiments of the present disclosure;

FIGS. 4A and 4B are perspectives of printed structures according to illustrative embodiments of the present disclosure;

FIGS. 5A-5C are successive cross sections of structures following the flow diagrams of FIGS. 3A and 3B according to illustrative embodiments of the present disclosure;

FIG. 6 is a cross section of a printed structure according to illustrative embodiments of the present disclosure;

FIGS. 7-9 are cross sections of printed structures according to illustrative embodiments of the present disclosure;

FIG. 10 is a perspective of a printed structure according to illustrative embodiments of the present disclosure;

FIG. 11A is an exploded perspective of a printed structure with components shown at different angles, FIG. 11B is an exploded cross section taken along cross section line A of FIG. 11A, and FIG. 11C is a cross section taken along cross section line A of FIG. 11A according to illustrative embodiments of the present disclosure;

FIG. 12 is a cross-section of a component with connection posts according to illustrative embodiments of the present disclosure;

FIG. 13A is a perspective of a component in alignment with structures on a target substrate according to illustrative embodiments of the present disclosure;

FIG. 13B is a perspective of a component in alignment with structures disposed in a target substrate cavity according to illustrative embodiments of the present disclosure;

FIG. 13C is a perspective of a component disposed in a target substrate cavity in alignment with structures formed by walls of the cavity according to illustrative embodiments of the present disclosure;

FIG. 13D is a perspective of multiple components disposed in a target substrate cavity in alignment with structures formed by walls of the cavity according to illustrative embodiments of the present disclosure;

FIG. 14A is a plan view of a component in alignment with structures on a target substrate according to illustrative embodiments of the present disclosure;

FIG. 14B is a plan view of a component having a component edge at a component end that is orthogonal to the length direction of the component in alignment with structures on a target substrate according to illustrative embodiments of the present disclosure;

FIG. 14C is a plan view of a component having an angled component edge at a component end that is not orthogonal to the length direction of the component in alignment with structures on a target substrate wherein one structure has an edge that is angled away from another structure according to illustrative embodiments of the present disclosure;

FIG. 14D is a plan view of a component having an angled component edge at a component end that is not orthogonal to the length direction of the component in alignment with structures on a target substrate wherein one structure has an edge that is angled toward another structure according to illustrative embodiments of the present disclosure;

FIG. 15 is a plan view of a component having component ends with angled component edges in alignment with and parallel to edge walls of structures 20 on a target substrate according to illustrative embodiments of the present disclosure;

FIG. 16 is a perspective of a component with component structures in a cavity adhered to a target substrate cavity bottom surface in alignment with a substrate structure cavity wall according to illustrative embodiments of the present disclosure;

FIGS. 17A-17F are successive cross sections of printed structures according to illustrative embodiments of the present disclosure;

FIG. 18 is a flow diagram according to illustrative embodiments of the present disclosure; and

FIGS. 19A-19C are flow diagrams according to illustrative embodiments of the present disclosure.

FIG. 20 is a cross section of a component pushing adhesive horizontally along a target substrate surface to form a bulge or protuberance of adhesive on the surface between the component and a structure useful in understanding embodiments of the present disclosure;

FIG. 21A is a plan view of a component having an angled component edge at a component end that is not orthogonal to the length direction of the component in alignment with structures on a target substrate wherein one structure has an edge that is angled away from another structure to form a gap according to illustrative embodiments of the present disclosure;

FIG. 21B is a plan view of a component with a cut-off corner forming a gap in alignment with an angled structure according to illustrative embodiments of the present disclosure;

FIG. 21C is a plan view of a component in alignment with a structure having an indentation forming a gap according to illustrative embodiments of the present disclosure;

FIG. 21D is a plan view of a component having an angled component edge at a component end that is not orthogonal to the length direction of the component in alignment with structures on a target substrate wherein one structure has an edge that is angled toward another structure to form a gap according to illustrative embodiments of the present disclosure;

FIG. 22A is a cross section of a component adhered to a target substrate surface in alignment with a structure and with a gutter in the target substrate laterally between the component and the structure according to illustrative embodiments of the present disclosure;

FIG. 22B is a cross section of a component adhered to a target substrate surface in alignment with a structure and with a gutter in the target substrate partially laterally between the component and the structure and partially under the component according to illustrative embodiments of the present disclosure;

FIG. 22C is a cross section of a component adhered to a target substrate surface in alignment with a structure and with a gutter in the target substrate aligned with a structure edge of the structure laterally between the component and the structure according to illustrative embodiments of the present disclosure;

FIG. 22D is a cross section of a component adhered to a target substrate surface in alignment with a structure and with a gutter in the target substrate aligned with a structure edge of the structure under the component according to illustrative embodiments of the present disclosure; and

FIGS. 23-25 are flow diagrams according to illustrative embodiments of the present disclosure.

Features and advantages of the present disclosure will become more apparent from the detailed description set forth below when taken in conjunction with the drawings, in which like reference characters identify corresponding elements throughout. In the drawings, like reference numbers generally indicate identical, functionally similar, and/or structurally similar elements. The figures are not necessarily drawn to scale.

### DETAILED DESCRIPTION OF CERTAIN EMBODIMENTS

Certain embodiments of the present disclosure are directed toward methods of printing (e.g., micro-transfer printing) components from a component source wafer onto a target substrate using a transfer element (e.g., stamp or other transfer device), and to structures extending or protruding from a surface of the target substrate. The structures can be used to align components to a location on the target substrate, to the structure, or to another component. Transfer-printed components are moved both vertically and horizontally over the target substrate to contact the structure and position the component on the target substrate with respect to the structure. The structure and the component can be aligned optical components.

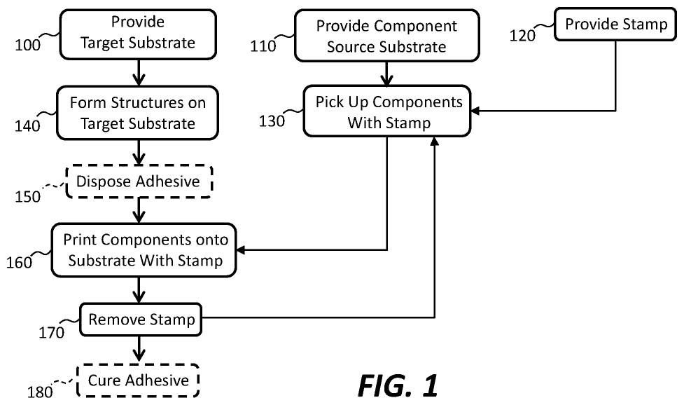

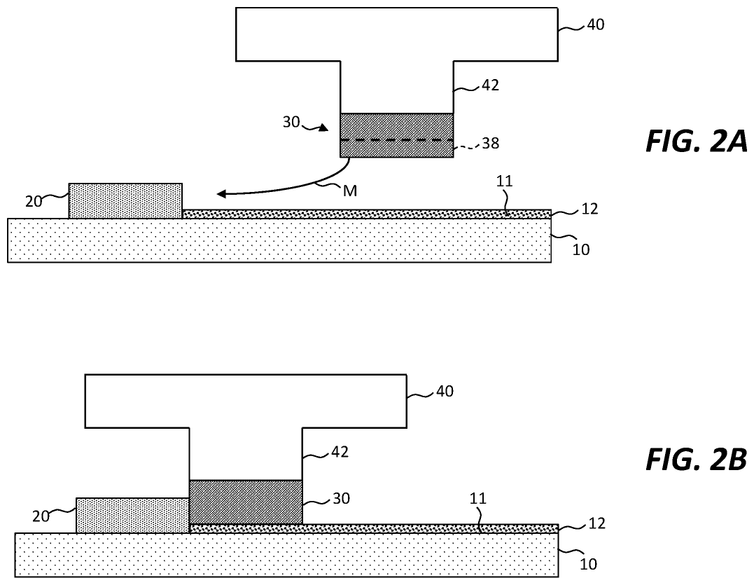

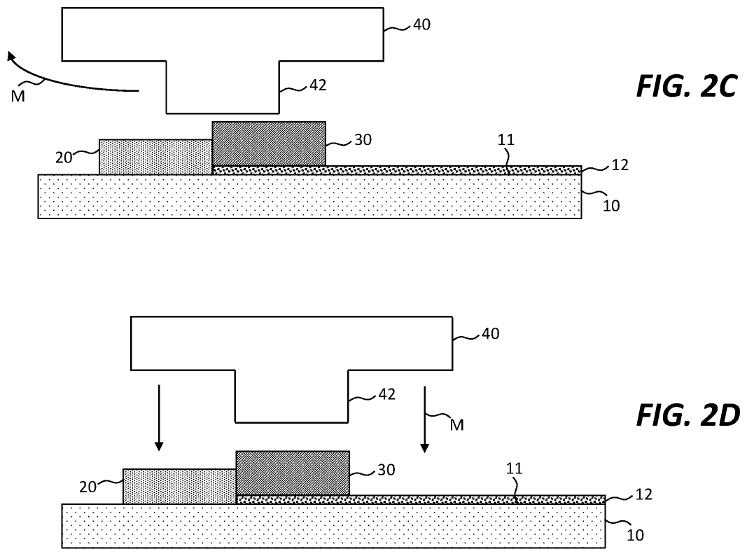

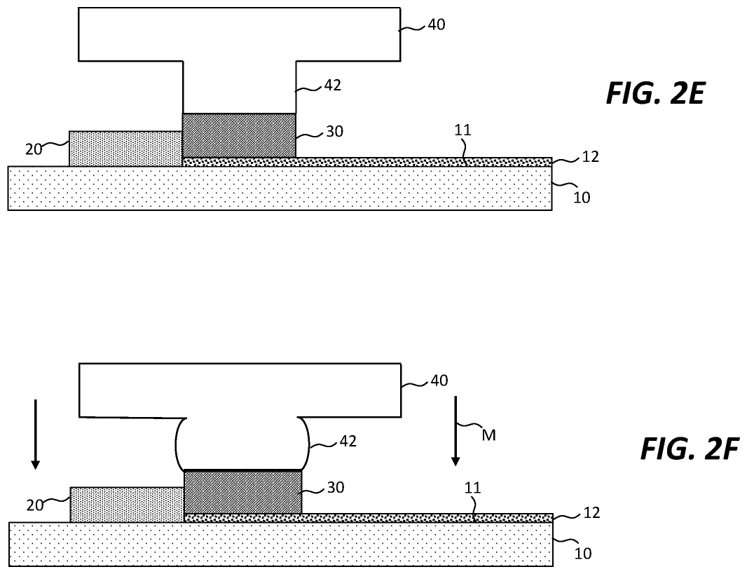

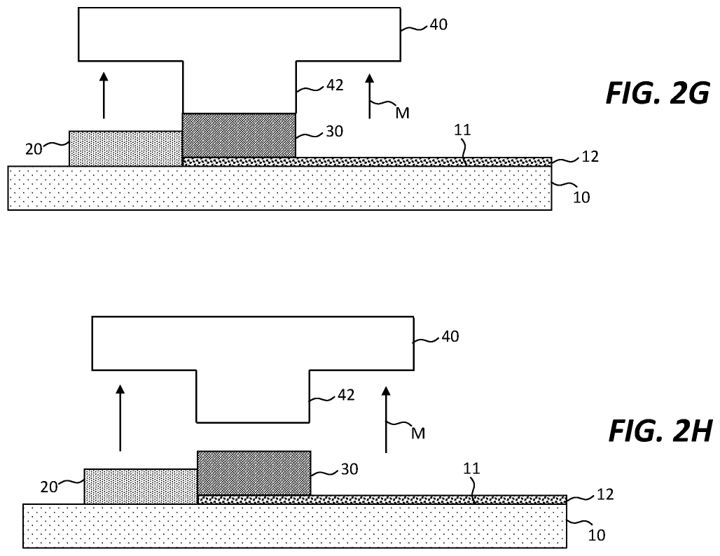

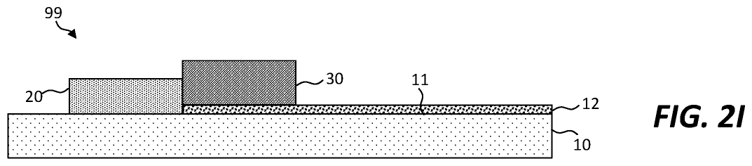

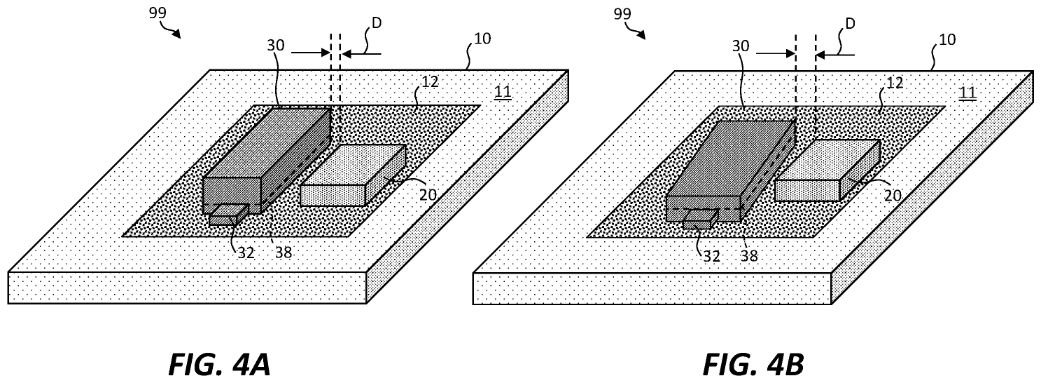

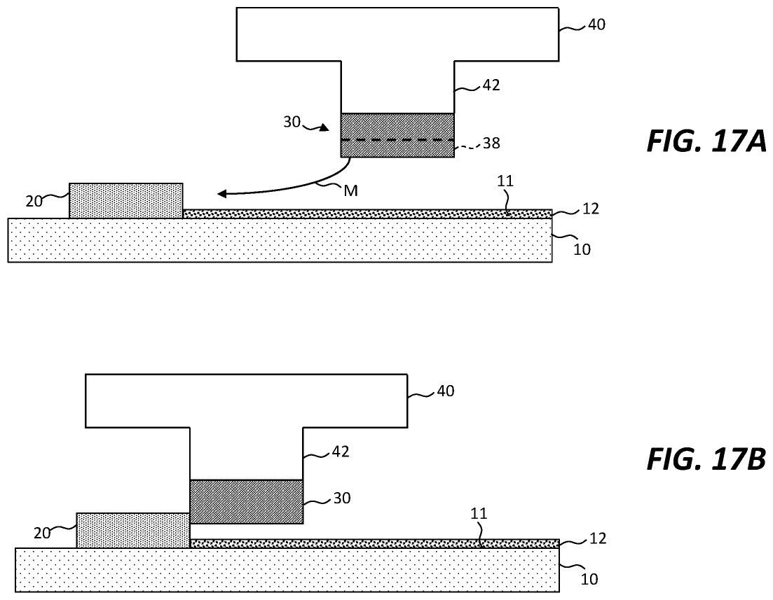

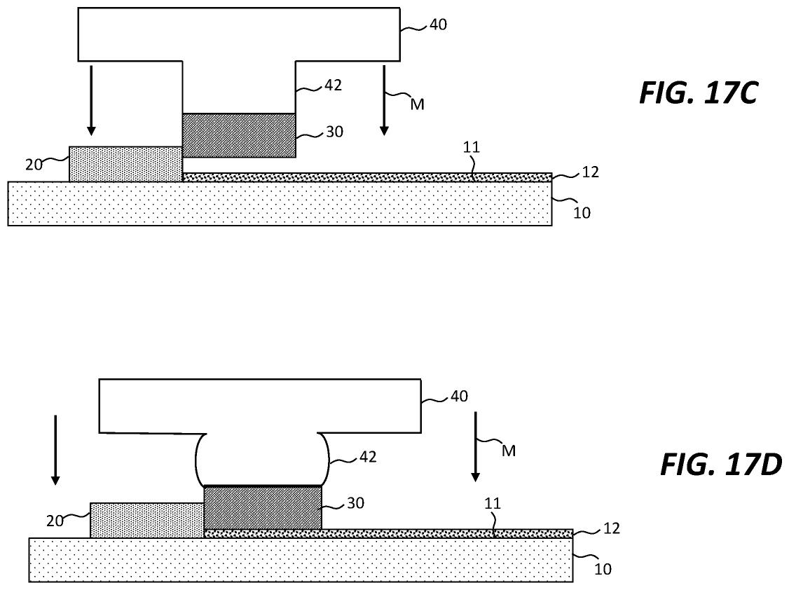

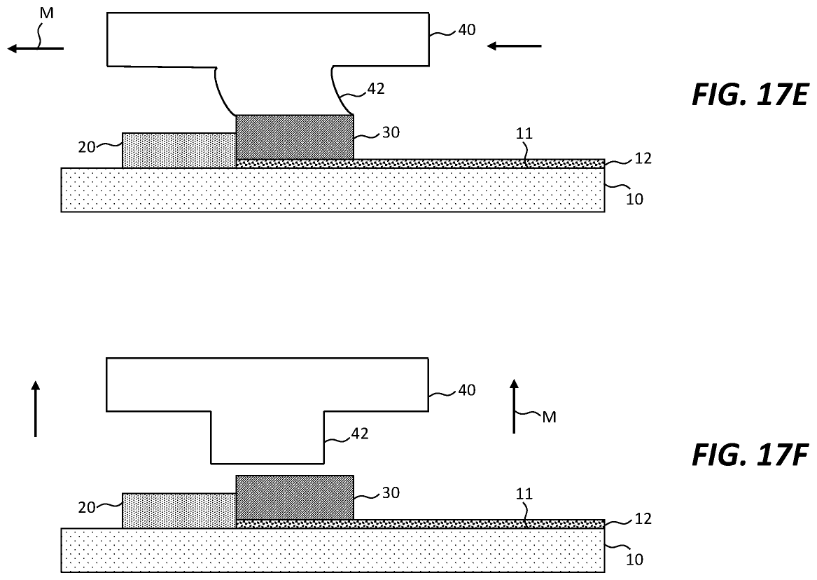

Referring to the flow diagram of FIG. 1 and the successive cross sections and perspectives of FIGS. 2A-2I and 17A-17F, according to some embodiments of the present disclosure a method of making a printed structure 99 comprises providing a target substrate 10 and a structure 20 (e.g., a substrate structure 20) protruding from a surface 11 of target substrate 10 in step 100. Optionally, substrate 10 is provided without structure 20 and structure 20 is constructed on or adhered to target substrate 10 in step 140. Structure 20 can be disposed, e.g., by micro-transfer printing, on surface 11 of target substrate 10 or target substrate 10 can comprise structure 20. Structure 20 can be formed or constructed on target substrate 10. A component source substrate such as a wafer substrate comprising native printable (e.g., micro-transfer printable) components 30 disposed thereon is provided in step 110. Each component 30 can comprise a component substrate 38 separate and independent from target substrate 10 (shown in FIGS. 2A and 4 but omitted elsewhere for clarity) and from structure 20. A component substrate 38 can be, for example, a portion of the native wafer substrate or component source wafer or substrate on which component 30 is formed or constructed. A transfer element 40 (e.g., a viscoelastic stamp 40 with a stamp post 42) can be provided in step 120 and a component 30 adhered to transfer element 40 (for example to stamp post 42) by picking up component 30 from the component source substrate in step 130. In the present disclosure, for simplicity and clarity stamp 40 is referred to interchangeably with transfer element 40, but transfer element 40 is not limited to a stamp embodiment. Certain embodiments of the present disclosure contemplate and include transfer elements 40 other than stamps, for example vacuum, magnetic, and electrostatic grippers that are used to print components 30, structures 20, or both components 30 and structures 20, to target substrate 10. An optional adhesive layer 12 is optionally applied to surface 11 of target substrate 10 in optional step 150. Adhesive layer 12 can be coated on surface 11 of target substrate 10 or can be surface 11 of target substrate 10.

In step 160, transfer element 40 and adhered component 30 are moved vertically toward surface 11 of target substrate 10 and horizontally towards structure 20 in movement direction M (shown in FIG. 2A and FIG. 17A), either simultaneously or alternatively (e.g., first vertically and then horizontally, or vice versa), until component 30 physically contacts (e.g., directly contacts, strikes, or presses against) structure 20 (shown in FIG. 2B) or is adhered to surface 11 of target substrate 10 within a separation distance D that is within one micron (e.g., within 1.0 micron, within 0.75 microns, within 0.5 microns, within 0.25 microns, or within 0.1 microns) of structure 20. Transfer element 40 is separated (e.g., removed) from component 30 and target substrate 10 (shown in FIG. 2C) in step 170. Separation step 170 can comprise a movement of transfer element 40 in movement direction M such as only a vertical movement away from surface 11 of target substrate 10, for example as shown in FIGS. 2G and 2H or as exemplified in FIG. 2C, can comprise both a vertical movement away from surface 11 of target substrate 10 and a horizontal movement in a direction parallel to surface 11 of target substrate 10. Optionally, separation during step 170 can comprise movement such that at least a portion of stamp 40 or stamp post 42 moves toward structure 20, for example so that structure 20 scrapes component 30 off of stamp 40 or stamp post 42.

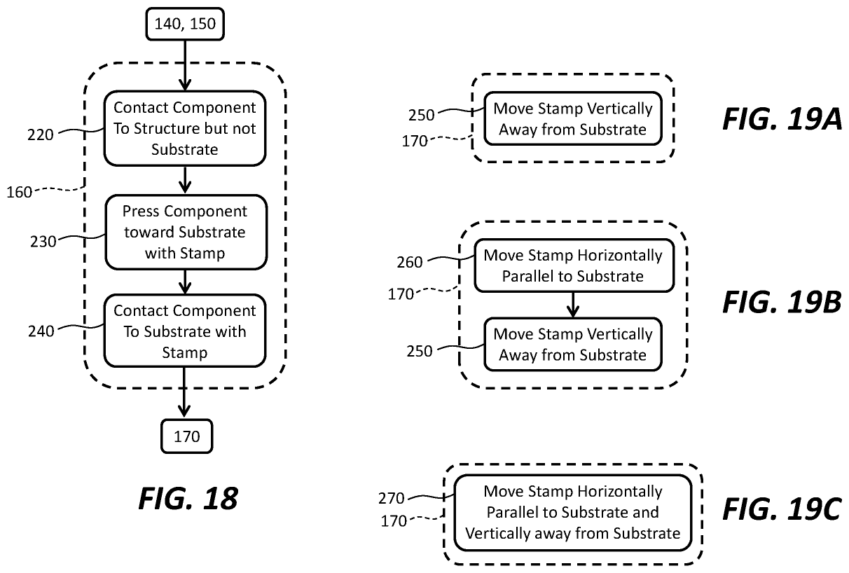

In some embodiments, and as shown in the FIG. 17B cross section and FIG. 18 flow diagram, to print components 30 onto target substrate 10 in step 160, transfer element 40 and adhered component 30 can move at least horizontally (e.g., in a direction parallel to a surface 11 of target substrate 10) until component 30 contacts structure 20 but does not contact surface 11 of target substrate 10 (does not contact optional adhesive layer 12, if present) in step 220. Transfer element 40 and adhered component 30 can then move vertically (e.g., in a direction perpendicular to a surface 11 of target substrate 10), for example as shown in FIG. 17C in step 230 until component 30 contacts contact surface 11 of target substrate 10 (or optional adhesive layer 12 thereon), as shown in FIG. 17D in step 240. Transfer element 40 can compress (e.g., stamp post 42 can compress) and provide pressure against component 30 to firmly contact component 30 contact surface 11 of target substrate 10 or optional adhesive layer 12. Transfer element 40 can then be removed in step 170, for example by simply moving transfer element 40 vertically in step 250 and as shown in FIGS. 2G and 19A. In some embodiments, transfer element 40 first moves horizontally in step 260 (e.g., as shown in FIG. 17E) and then second moves vertically in step 250 (e.g., as shown in FIGS. 17F and 19B). The horizontal movement in step 260 can deform stamp post 42 and can delaminate the distal end of stamp post 42 from component 30, for example the trailing edge of distal end of stamp post 42, facilitating component 30 removal from stamp post 42. Transfer element 40 can then move vertically in step 250, leaving component 30 adhered to target substrate 10 or optional adhesive layer 12 in close proximity to or in contact with, structure 20, for example as shown in FIG. 17F. In some embodiments, transfer element 40 moves both horizontally and vertically in step 270 to firmly contact component 30 against structure 20 (e.g., as shown in FIGS. 2C), leaving component 30 adhered to target substrate 10 or optional adhesive layer 12 in close proximity to or in contact with, structure 20.

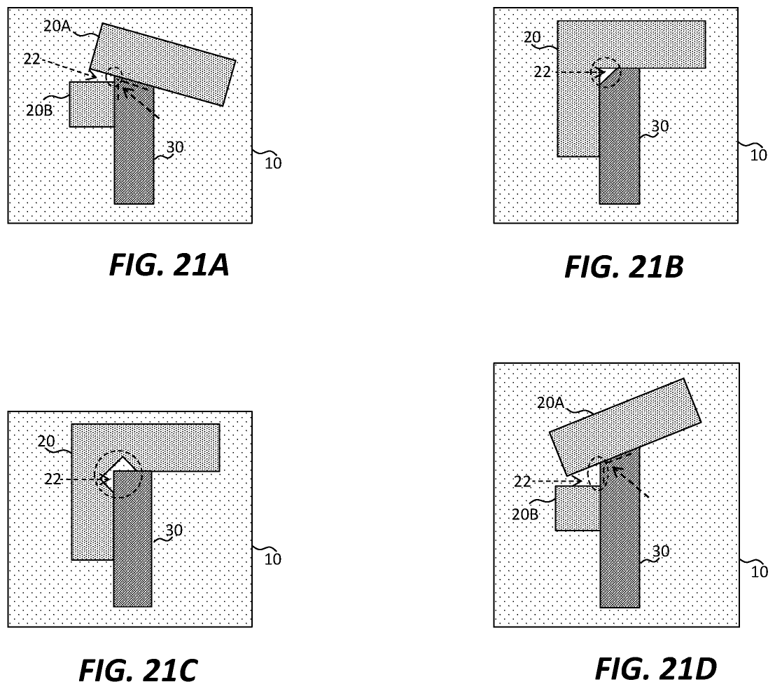

At the conclusion of separation step 170, component 30 is disposed on target substrate 10 within a separation distance D of structure 20 (e.g., as shown in FIGS. 4A, 4B). For example, component 30 can be in contact with structure 20 at the conclusion of separation step 170 (e.g., as shown in FIGS. 21 and 17F). Multiple components 30 can be picked up and transferred as shown with the flow diagram arrow from step 170 to step 130 in FIG. 1. In certain embodiments, if optional adhesive layer 12 is provided in optional step 150, adhesive layer 12 is curable and is then optionally cured in optional step 180.

As used herein, vertical movement is defined as movement in a direction M substantially or effectively orthogonal to surface 11 of target substrate 10 and horizontal movement in a direction M is defined as movement substantially or effectively parallel to surface 11 of target substrate 10. A movement of transfer element 40 toward structure 20 means that at least a portion of transfer element 40 is moving toward structure 20, for example horizontally or vertically or both horizontally and vertically. A component 30 can be separated from transfer element 40 by moving transfer element 40 toward structure 20 at least horizontally and optionally vertically toward structure 20. Movement in a direction M can be temporally continuous or discontinuous, can move simultaneously in horizontal and vertical directions, or can alternate in horizontal and vertical directions. Movement can be in a straight line or in a curved line. A transfer element 40 can accelerate or decelerate during movement.

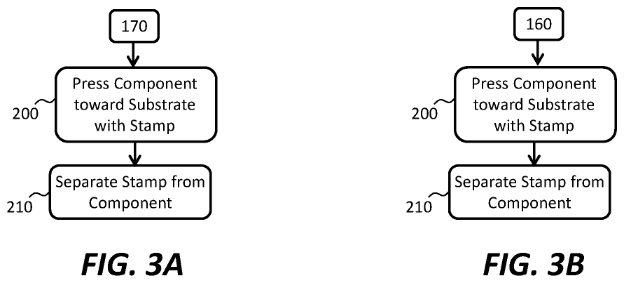

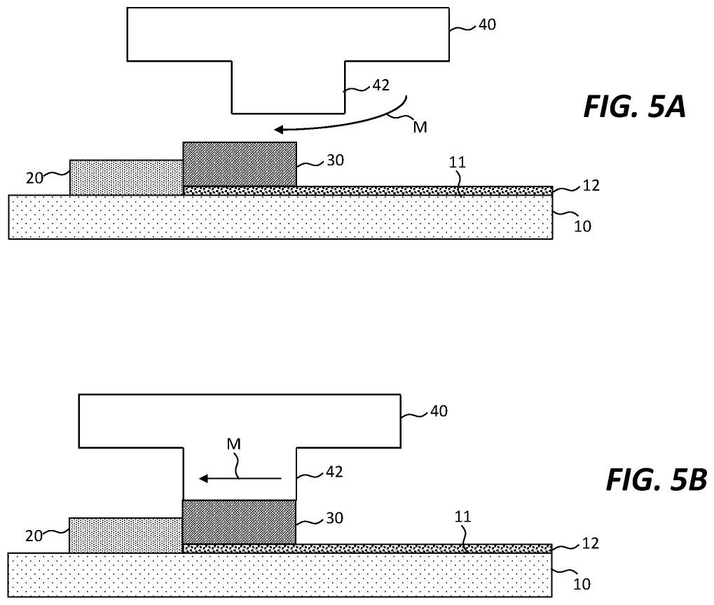

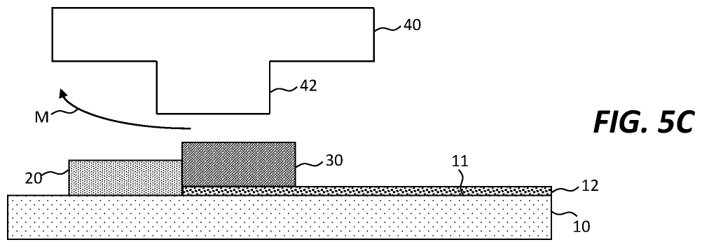

Depending on the amount and force of vertical motion in step 160, it can be helpful to additionally or repeatedly press component 30 toward (e.g., onto) surface 11 of target substrate 10, for example such that component 30 moves onto or into a layer such as adhesive layer 12 disposed on surface 11 of target substrate 10 after the conclusion of step 160 (as shown in FIG. 3B) or step 170 (as shown in FIG. 3A). If adhesive layer 12 is present, component 30 can be pressed on or into adhesive layer 12 and adhered to target substrate 10. Referring to the flow diagram of FIG. 3A, FIGS. 2D-2H, and FIGS. 5A-5C, after stamp 40 is separated (e.g., removed) from component 30 in step 170, stamp 40 is then moved in direction M toward surface 11 of target substrate 10 in step 200 (e.g., vertically as shown in FIG. 2D) and component 30 is pressed onto surface 11 of target substrate 10 (e.g., as shown in FIG. 2E). As shown in FIG. 2F, the vertical motion of stamp 40 in direction M can compress stamp post 42. Stamp 40 is then moved in direction M vertically (e.g., as shown in FIGS. 2G and 2H) away from surface 11 of target substrate 10 in step 210 as in step 170. According to some methods of the present disclosure, transfer element 40 moves in direction M both horizontally and vertically toward target substrate 10 (e.g., as shown in FIG. 5A), contacts component 30 (e.g., as shown in FIG. 5B) in step 200 and then continues a horizontal and vertical motion in direction M away from target substrate 10 (e.g., as shown in FIG. 5C) in step 210. To facilitate contact between structure 20 and component 30 and enable movement of stamp 40, component 30 can have a thickness equal to or greater than a thickness of structure 20, so that transfer element 40 (e.g., stamp post 42 thereof) does not strike or otherwise physically contact structure 20 when transfer-printing component 30 to target substrate 10 or when separating stamp 40 from target substrate 10 (in steps 170, 210).

Referring to the flow diagram of FIG. 3B, FIGS. 2D-2H, and FIGS. 5A-5C, in some embodiments of the present disclosure, stamp 40 presses component 30 onto surface 11 of target substrate 10 after printing in step 160 but before stamp 40 is separated from component 30 (in step 170). Because transfer element 40 can comprise compressible viscoelastic materials, transfer element 40 can move vertically while maintaining contact with component 30, as shown in FIG. 2F. In some such embodiments, pressure is applied to component 30 by stamp 40 to micro-transfer print component 30 onto target substrate 10 in step 160. Optionally, pressure from stamp 40 is reduced but stamp post 42 remains in contact with component 30, and then pressure from stamp 40 is increased in step 200 and as shown in FIG. 2F to firmly position and adhere component 30 on target substrate 10 in alignment with structure 20, for example as shown in FIG. 2F. Stamp 40 is then separated (e.g., removed) from component 30 in step 210 (using vertical motion only, for example as shown in FIGS. 2G-2H, or using additional horizontal motion, for example as shown in FIGS. 2C and 5C). The steps of FIGS. 3A and 3B, FIGS. 2D-2H, or FIGS. 5A-5C can be iteratively repeated if necessary and as desired to properly position or adhere component 30, or both, with respect to structure 20 and on target substrate 10.

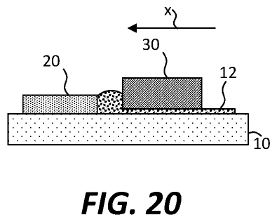

In some embodiments of the present disclosure component 30 is above and not in contact with surface 11 of target substrate 10 when component 30 physically contacts structure 20 due to movement of transfer element 40 (e.g., as shown in FIG. 17B). In some embodiments of the present disclosure component 30 is in direct contact with surface 11 of target substrate 10 or is in direct contact with an adhesive layer 12 disposed on target substrate 10 (e.g., disposed in contact with surface 11 of target substrate 10 through adhesive layer 12) when component 30 physically contacts structure 20 (e.g., as shown in FIG. 20 discussed below).

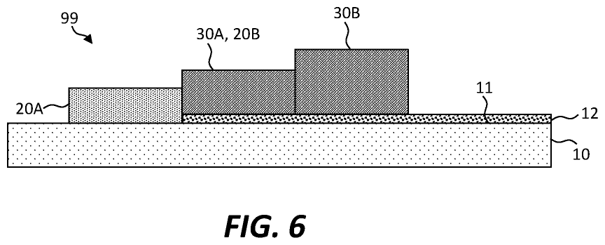

Some methods of the present disclosure can be iteratively repeated so that components 30 disposed on target substrate 10 can subsequently serve as a structure 20 when another component 30 is disposed on target substrate 10 (or on adhesive layer 12 disposed on surface 11 of target substrate 10) using the methods described above. Referring to FIG. 6, a first structure 20A is disposed on target substrate 10 and a first component 30A is disposed within a separation distance D (e.g., as shown in FIG. 4A). For example, first component 30A can be disposed in contact with first structure 20A (e.g., as shown in FIGS. 21 and 6) at a first time. At a second time later than the first time, second component 30B is disposed within a separation distance D (e.g., as shown in FIG. 4A). For example, second component 30B can be disposed in contact with first component 30A (second structure 20B, e.g., as shown in FIGS. 21 and 6) at the second time. When disposing second component 30B, first component 30A serves as a structure 20 (e.g., second structure 20B) for second component 30B so that second component 30B is aligned with first component 30A after disposition.

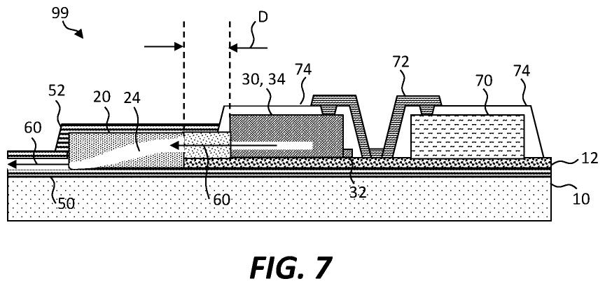

Some methods of the present disclosure accomplish component 30 transfers using micro-transfer printing (e.g., dry contact printing). Such printing methods can transfer components 30 formed on a native component source substrate. The component source substrate is processed to release components 30 (with component substrate 38) from the component source substrate so that components 30 are physically attached to the component source substrate only with one or more tethers 32 physically connecting components 30 to one or more anchors of the component source substrate. A stamp 40 contacts one or more components 30, adhering component 30 to stamp 40 (for example, to a stamp post 42). Stamp 40 separates and removes components 30 from the component source wafer, breaking (e.g., fracturing) or separating each tether 32 physically connecting each component 30 to the native component source wafer. For clarity, broken or separated tethers 32 are omitted from FIGS. 2A-2I and 5A-5C, but broken or separated tethers 32 are shown in FIGS. 4A and 4B (and FIGS. 7-11B discussed below). Stamp 40 then contacts the one or more components 30 adhered to stamp posts 42 to a target substrate 10.

Referring to FIGS. 2I, 4A, 4B, and 6, such a printed structure 99 can comprise a target substrate 10 having a structure 20 protruding from a surface 11 of target substrate 10. Structure 20 can be disposed with adhesive layer 12 between structure 20 and target substrate 10. A component 30 is non-native to target substrate 10 (e.g., component 30 comprises a component substrate 38 separate and independent from target substrate 10). Component 30 can be disposed on surface 11 of target substrate 10 within one micron (e.g., within 1.0 micron, within 0.75 microns, within 0.5 microns, within 0.25 microns, or within 0.1 microns) of structure 20 (for example as shown in FIG. 4A). In some embodiments, component 30 is disposed in alignment with (e.g., substantially parallel to or no more than slightly askew relative to) structure 20. FIG. 4B shows an example printed structure 99 where component 30 is slightly askew relative to structure 20 and disposed within distance D (e.g., within one micron) of structure 20. In some embodiments, component 30 disposed within distance D of structure 20 has no portion of a face of component 30 that is adjacent to a face of structure 20 further than distance D away from the face of structure 20. In some embodiments, component 30 comprises a broken or separated tether 32. In some embodiments, component 30 is in contact with structure 20 (e.g., as shown in FIG. 2I) and component 30 is therefore within a separation distance D from structure 20 equal to zero microns. In some embodiments, structure 20 is also a transferred component 30 and comprises a broken (e.g., fractured), or separated tether 32 (not shown in the Figures).

If a second component 30 (e.g., second component 30B, as shown in FIG. 6) is disposed on target substrate 10 in alignment with and relatively close to a structure 20, (for example as shown in FIG. 4A), or a first component 30A (for example as shown in FIG. 6), second component 30B can be disposed on surface 11 of target substrate 10 within 1 micron, e.g., within 1.0 micron, within 0.75 microns, within 0.5 microns, within 0.25 microns, or within 0.1 microns of first component 30A (or structure 20). For example, second component 30B can be in contact with first component 30A (or structure 20). Second component 30B can comprise a broken or separated tether 32. In some embodiments, first component 30A and second component 30B are disposed in alignment with a common structure 20.

Micro-transfer printing is especially useful when transferring or otherwise disposing components 30 (e.g., first or second components 30A, 30B, or both) that are relatively small. In some embodiments, for example, component 30 has a length, a width, or both a length and a width less than or equal to 200 microns, e.g., less than or equal to 100 microns, less than or equal to 50 microns, less than or equal to 20 microns, less than or equal to 10 microns, less than or equal to 5 microns, less than or equal to 2 microns, or less than or equal to 1 micron in length or width and, optionally also has a thickness less than or equal to 50 microns, e.g., less than or equal to 25 microns, less than or equal to 10 microns, less than or equal to 5 microns, less than or equal to 2 microns, less than or equal to one micron, less than or equal to 0.5 microns, less than or equal to 0.2 microns, or less than or equal to 0.1 microns.

According to some embodiments of the present disclosure and as shown in FIG. 7, a printed structure 99 can comprise aligned components 30 or structures 20 that receive or emit light 60 (e.g., are operable to receive or emit light 60), such as photonic components 30 or photonic structures 20. Photonic components 30 or photonic structures 20 can be or include, for example, light pipes 24, light guides, or optical fibers that conduct light 60, light-emitting diodes, lasers, laser diodes, light sensors, or photodetectors. Thus, according to some embodiments of the present disclosure, the structure 20, the component 30, or both the structure 20 and the component 30 are operable to receive or emit light, both structure 20 and component 30 comprise a light pipe and the light pipe in structure 20 is in alignment with the light pipe in component 30, structure 20 comprises a light pipe and component 30 comprises a light emitter or light sensor in alignment with the light pipe in structure 20, or component 30 comprises a light pipe and structure 20 comprises a light emitter or light sensor in alignment with the light pipe in component 30.

In some embodiments, adhesive layer 12 is substantially transparent to light 60 that is received or emitted by components 30 or structures 20. A substantially transparent adhesive layer 12 is one that does not compromise the effective transmission of light 60 received or emitted by components 30 or structures 20, for example an adhesive layer 12 comprising an adhesive that is at least 50%, e.g., at least 75%, at least 80%, at least 85%, at least 90%, or at least 95% transparent to light 60 received or emitted by components 30 or structures 20. In some embodiments, adhesive layer 12 can conduct light 60, for example serve as, or as a portion of, a light pipe 24 (e.g., a light guide or fiberoptic channel) or can transmit light 60 between component 30 and structure 20. In some embodiments, an encapsulation layer 74 (for example, a dielectric layer 74) is disposed at least partly over any combination of component 30, structure 20, and any gap between component 30 and structure 20. Such a gap, for example can define or be a separation distance D as described above. Encapsulation layer 74 can comprise a light-reflective layer or encapsulation layer 74 can be coated with a light-reflective layer (for example upper light-reflective layer 52). Such a light-reflective layer, together with lower light-reflective layer 50, can control and direct light 60 as desired with respect to components 30 and structures 20.

In some embodiments, emitted or received light 60 is controlled or conducted by material optical index differences, for example as in a fiber-optic device. According to some embodiments, component 30 comprises a component material, target substrate 10 comprises a substrate material, and the component material is substantially different from the substrate material, for example comprising different material, having different material transparency, reflection, or absorption, or having different optical indices (e.g., having at least a 10% difference in refractive index). In some embodiments, target substrate 10 comprises a reflective material disposed between component 30 and target substrate 10 or between structure 20 and target substrate 10, e.g., lower light-reflective layer 50.

Referring to FIG. 7, target substrate 10 comprises or has disposed upon it a lower light-reflective layer 50 for example a patterned metal layer such as silver or aluminum that is sputtered or evaporatively deposited and patterned, for example using photolithographic methods and materials. Adhesive layer 12 is optionally disposed on target substrate 10 and lower light-reflective layer 50, for example by coating a curable liquid resin. Structure 20, for example comprising light pipe 24, is formed or disposed on target substrate 10 and lower light-reflective layer 50, for example using photolithographic methods and materials such as patterned silicon dioxide, silicon nitride, resins such as epoxies, and reflective materials, such as metals. Upper light-reflective layer 52 can be disposed over structure 20. Component 30 comprising micro-laser 34 (e.g., micro-diode laser 34) is disposed on target substrate 10 (for example by micro-transfer printing as described in FIG. 2A-2I and comprising a broken (e.g., fractured) or separated tether 32) adjacent to structure 20 within a separation distance D. Component 30 is optically aligned with structure 20 so that light-emitting diode micro-laser 34 emits laser light 60 into light pipe 24. In the illustration of FIG. 7, adhesive material, for example a portion of adhesive layer 12 is disposed between component 30 and structure 20 to fill any gap that would otherwise exist between component 30 and structure 20. The portion of adhesive layer 12 is effectively or substantially transparent to light 60 emitted micro-laser 34 and does not inhibit the effective transmission of light 60 between micro-laser 34 and light pipe 24.

As shown, for example, in FIG. 7, an integrated circuit 70, for example a controller, can also be disposed on target substrate 10, for example by micro-transfer printing. Integrated circuit 70 can be electrically connected to component 30, to structure 20, or to both controller 30 and structure 20, and can be operable to control component 30, to control structure 20, or to control both controller 30 and structure 20. Integrated circuit 70 can have a broken (e.g., fractured) or separated tether 32 (not shown in FIG. 7). A dielectric encapsulation layer 74 can be disposed over either or both of component 30 and integrated circuit 70 and patterned to enable an electrically conductive electrode 72 to be disposed over target substrate 10, component 30, and integrated circuit 70 to electrically connect component 30, and integrated circuit 70 and enable integrated circuit 70 to control component 30 (micro-laser 34) to emit light 60 into structure 20 (light pipe 24). Upper light-reflective layer 52 and lower light-reflective layer 50 can be patterned layers that, in combination with patterned organic or inorganic dielectric layers can form light pipes 24 that conduct or transmit light 60 from one location over or in target substrate 10 to another location over or in target substrate 10 and implement at least a portion of a photonic system, for example a computing or communication system. In some embodiments, upper light-reflective layer 52 can be disposed over structure 20, component 30, or both and lower light-reflective layer 50 can be disposed under structure 20, component 30, or both to assist in controlling light 60 or forming light pipes 24.

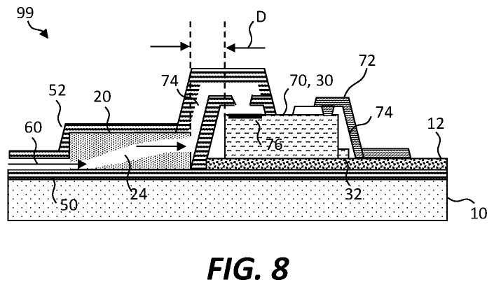

Referring to FIG. 8, in some embodiments of the present disclosure, component 30 is a light-receiving device, for example a photodetector or photosensor 76 in or of an integrated circuit 70, disposed in alignment with and within a separation distance D from structure 20 comprising a light pipe 24 adhered to target substrate 10 with adhesive layer 12. Light 60 travels between upper and lower light-reflective layers 52, 50, for example through a transparent patterned organic or inorganic encapsulation or dielectric layer 74 such as a layer of silicon dioxide or polymer and is directed to a photosensor 76 in component 30. Micro-transfer printed component 30 comprises a tether 32 and can be electrically connected by electrodes 72 to a source of power, ground, or control or response signals.

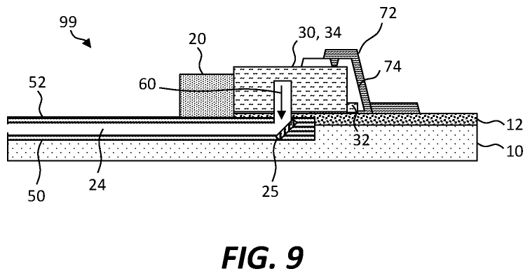

Referring to FIG. 9, light 60 can travel through light pipes 24 disposed within target substrate 10 rather than in patterned structures 20 provided on or above target substrate 10 in a printed structure 99 as in FIGS. 7 and 8. Light pipes 24 can comprise light reflectors 25 to assist in light 60 transport and conduction. As shown in FIG. 9, component 30 can be a light emitter such as a vertical-emitting diode micro-laser 34 (as opposed to the horizontal edge-emitting diode micro-laser 34 of FIG. 7) that receives power and control signals through electrodes 72 that are insulated from the semiconductor material of component 30 by patterned dielectric or encapsulation layers 74. In FIG. 9, structure 20 is an alignment structure that assists in positioning component 30 with respect to light pipe 24. Thus, according to some embodiments of the present disclosure, component 30 is disposed and operable to emit light to or receive light from target substrate 10, structure 20 is disposed and operable to emit light to or receive light from target substrate 10, or component 30 is disposed and operable to emit light to or receive light from target substrate 10.

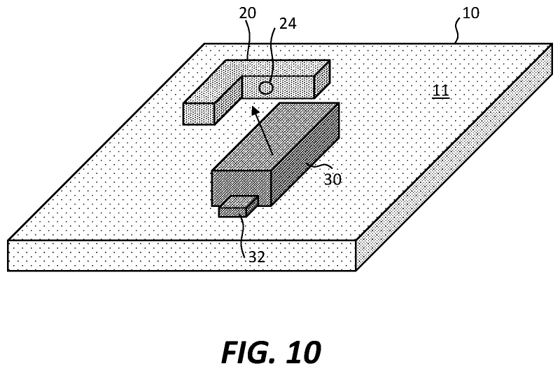

According to some embodiments of the present disclosure, and as shown in FIG. 10, structure 20 can have two or more structure faces that are not co-planar (two or more structure faces that are not in the same plane). Each individual structure face can be planar or non-planar, for example comprising a non-planar shape such as a curve or other non-flat shape). Component 30 can have one or more component faces complementary to the one or more structure faces, for example component faces matching those of structure 20. Complementary (e.g., matching) faces can fit closely together or can be in contact, or a portion of one face can fit into a matching or complementary other face. Such multiple component and structure faces can assist alignment of component 30 with structure 20 to prevent component 30 from being undesirably rotated with respect to structure 20. Thus, in some embodiments, component 30 is disposed on surface 11 of target substrate 10 within one micron (e.g., within 1.0 micron, within 0.75 microns, within 0.5 microns, within 0.25 microns, or within 0.1 microns) of the two-or-more non-planar faces of structure 20. In some embodiments, component 30 is disposed in contact with the two-or-more non-planar faces of structure 20 (and therefore has a separation distance D of zero microns). In some embodiments, a structure 20 and component 30 are within a separation distance D if any portion or structure face of structure 20 is in contact with or within separation distance D of any portion or component face of component 30.

As shown in FIG. 21, in some embodiments, (i) structure 20 has a flat face opposed to component 30, (ii) component 30 has a substantially flat face opposed to structure 20, or (iii) both (i) and (ii). The flat faces can be parallel to each other and thus enable close contact or a small separation distance between component 30 and structure 20. In some embodiments, structure 20 has a non-planar face opposed to component 30 and component 30 has a non-planar face complementary to the face of structure 20. According to some embodiments, at least a portion of the non-planar face of structure 20 is in contact with the non-planar face of component 30.

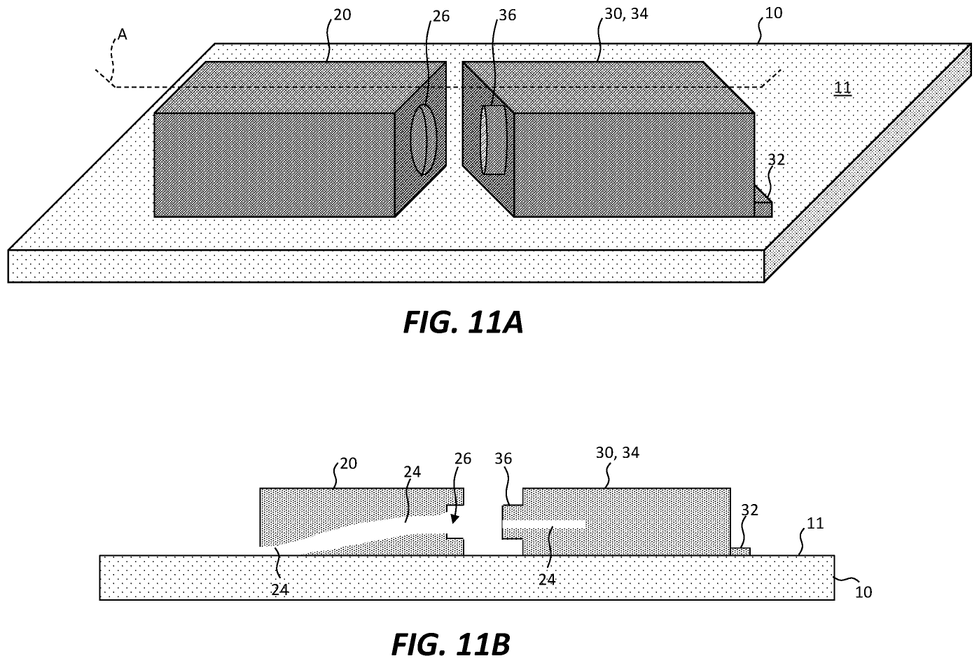

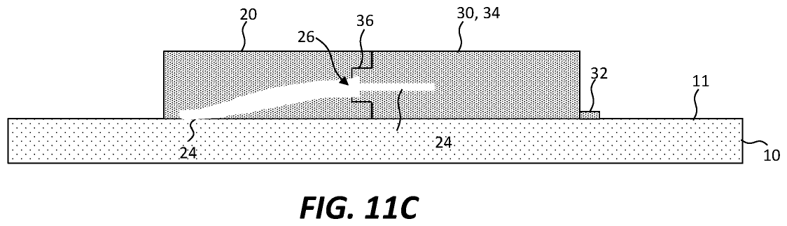

For example, referring to FIGS. 11A-11C, a face of component 30 can have a protrusion 36 (e.g., an extension) opposing a face of structure 20 having a complementary indentation (e.g., a cavity) 26. One non-planar face can, for example, spatially, structurally, and physically complement a second non-planar face. In some embodiments, a face of component 30 has an indentation 26 opposing a face of structure 20 having a complementary protrusion 36. Such protrusions 36 and indentations 26 can have complementary shapes and serve to align components 30 to structures 20 as components 30 are transferred to target substrate 10. Complementary shapes can fit together, for example a protrusion can fit within an indentation (whether or not the protrusion and indentation have cross sections that are substantially similar in shape and/or size, for example an indentation can be larger than a protrusion). If present on a structure 20 and component 30, a protrusion 36 can be at least partially inserted into a complementary indentation 26 when component 30 is disposed in alignment with structure 20. FIG. 11A is an exploded illustration of component 30 on target substrate 10 in alignment with structure 20 using different perspectives for component 30 and structure 20 to illustrate how component 30 and structure 20 can fit together. FIG. 11B shows an exploded cross section of component 30 on target substrate 10 in alignment with structure 20. FIG. 11C is a cross section of component 30 on target substrate 10 in alignment with structure 20 and with protrusion 36 inserted into indentation 26 that aligns respective optical elements with each other. In FIGS. 11A-11C, complementary protrusion 36 and indentation 26 of component 30 and structure 20, respectively, have substantially the same size and shape.

Thus, according to some embodiments of the present disclosure, a structure 20 of printed structure 99 has a structure face and component 30 has a component face opposed to the structure face. In some embodiments, either (i) the structure face has an indentation 26 and the component face has a protrusion 36 complementary to indentation 26 (e.g., in size and/or shape), or (ii) the structure face has a protrusion 36 and the component face has an indentation 26 complementary to protrusion 36 (e.g., in size and/or shape) so that protrusion 36 can be inserted into indentation 26.

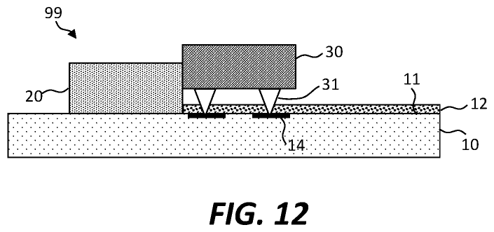

Referring to FIG. 12, according to some embodiments of the present disclosure, component 30 can comprise electrical connection posts 31 that provide an electrical connection from target substrate 10 to component 30. In some embodiments, connection posts 31 pierce or otherwise contact substrate contact pads 14 and are pressed into substrate contact pads 14, e.g., during micro-transfer printing, for example in step 160 or 200 (shown in FIG. 2B, 2D, or 2F) described above. In some embodiments, connection posts 31 are pressed into substrate contact pads 14 at least in part by reflowing a reflowable adhesive 12 (e.g., a resin). In some embodiments having components 30 with connection posts 31, it can be useful to contact structure 20 with component 30 before connection posts 31 of component 30 contact substrate contact pads 14 of target substrate 10. Connection posts 31 can be sharp (e.g., have a sharp point) for contacting or piercing an electrical contact pad, for example having a distal end with an area that is smaller (e.g., at least ten times smaller) than a base area. Connection posts 31 provide an electrical connection to component 30 without the need for subsequent photolithographic post processing to form electrodes 72, thus reducing the number of manufacturing steps.

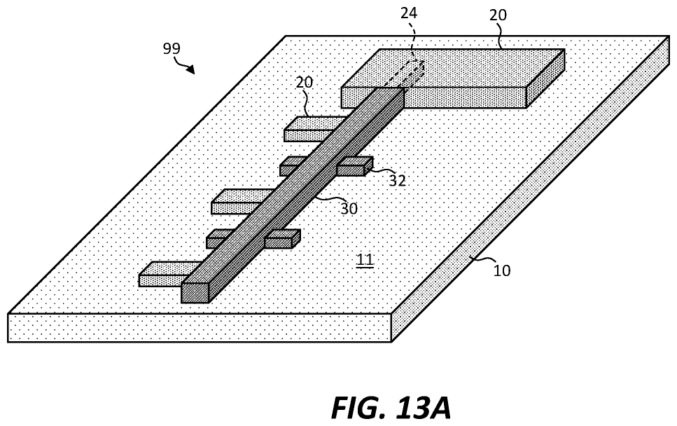

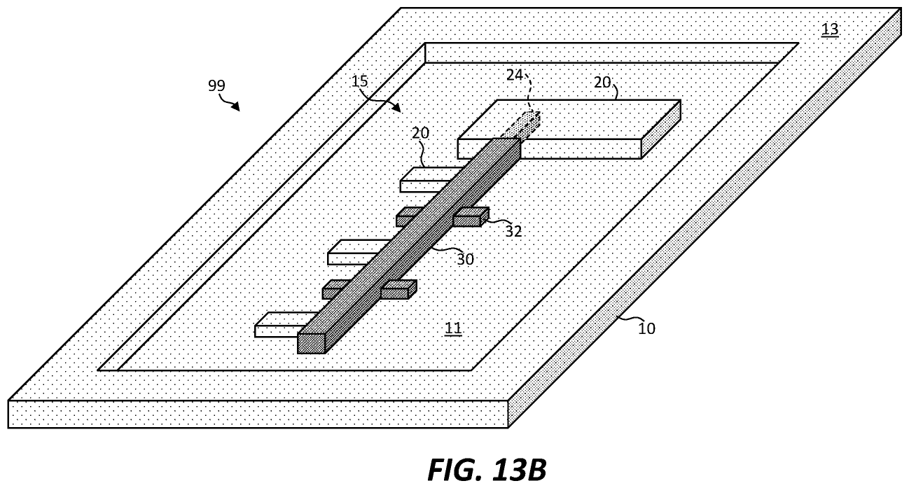

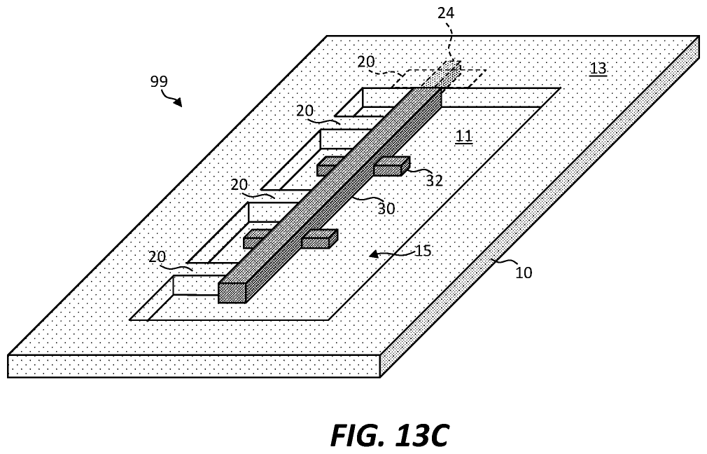

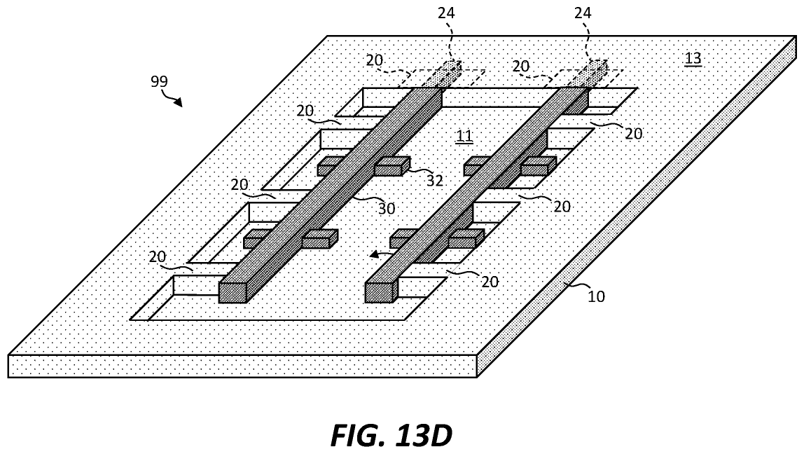

As discussed with respect to the embodiments illustrated in FIGS. 1-13, printed structures 99 can comprise a single alignment structure 20. In some embodiments of the present disclosure and as illustrated in FIGS. 13A-16, printed structures 99 comprise multiple, spatially separated and independent alignment structures 20 that extend from a surface 11 of target substrate 10. Component 30 can be disposed in alignment with one or more of structures 20, for example in alignment with two structures 20, in alignment with three structures 20, in alignment with four structures 20, or in alignment with all of structures 20. Structures 20 facilitate alignment of component 30 during micro-transfer printing component 30 to surface 11 by providing mechanical stops to locate and orient component 30 in a desired spatial position and orientation as component 30 moves over surface 11. Each component 30 can comprise a component substrate independent from and non-native to target substrate 10. Components 30 can be micro-transfer printed from a component source wafer to surface 11 of target substrate 10 and consequently comprise a broken (e.g., fractured) or separated tether 32.

As used herein, a length of component 30 is a dimension of component 30 that is longer than a width of component 30 in a direction parallel to surface 11. A component 30 can be longer in a length direction and shorter in a width direction and a component end is a side or face of component 30 having a component edge that is not parallel to the length direction. A component edge can be orthogonal to the length direction (and parallel to the width direction) or not orthogonal to the length direction (and not parallel to the width direction. A horizontal direction is parallel to surface 11 and a vertical direction is a direction orthogonal to surface 11. Laterally means in a horizontal direction parallel to surface 11 of target substrate 10. In some embodiments, component 30 and one or more structures 20 are disposed in alignment with each other such that component 30 is laterally adjacent to one or more structures 20 and no other structure 20 is closer to component 30 than one or more structures 20, for example each of one or more structures 20 can be disposed in contact with or within a distance of five micron or less (e.g., two microns or less or one micron or less). Alignment between component 30 and structure 20 can also mean that component 30 has a component edge (or side), structure 20 has a structure edge (or side), and the component edge and structure edge are substantially parallel within manufacturing and design limitations. Components 30 are non-native to target substrate 10 (e.g., constructed on a separate native component source wafer and transferred to target substrate 10). Structures 20 and components 30 can have a substantially flat face substantially orthogonal to surface 11, e.g., within manufacturing tolerances and limitations. Where structures 20 have a substantially flat face (e.g., wall) that is not orthogonal to surface 11, components 30 can have an edge (or side) that is no greater than one micron from the bottom of structure 20 adjacent to surface 11 or no greater than one micron from the top of structure 20 on a side of structure 20 opposite surface 11 (e.g., top surface 13). An edge of structure 20 or component 30 can also be a face, wall, or side of structure 20 or component 30.

In some embodiments and as shown in FIG. 13A, structures 20 are constructed on and native to target substrate 10, for example formed by depositing materials such as inorganic dielectrics (e.g., silicon dioxide or silicon nitride) or organic dielectrics such as resins, epoxies, and photoresists (e.g., SU8, Intervia, or benzocyclobutene-based (BCB) polymers), and patterning the deposited materials to form the structures 20. The structures 20 can comprise other elements, for example optical waveguides such as light pipes 24. In some embodiments, structures 20 can be disposed on and non-native to surface 11 of target substrate 10 and any one or more of structures 20 can be a component 30 disposed in separate steps on surface 11 so that a second component 30 can be aligned to a first component 30 acting as structure 20.

In some embodiments and as shown in FIGS. 13B and 13C, structures 20 extend from a bottom surface 11 of a cavity 15 (recess, hole, indentation) in target substrate 10, for example formed by pattern-wise etching cavity 15 into target substrate 10 from a top surface 13 of target substrate 10 or material deposition (e.g., by spin, spray, or curtain coating) and pattern-wise etching using photolithographic methods and materials, for example patterned masking, etching, and stripping. The bottom surface 11 of cavity 15 then forms surface 11 of target substrate 10 on which components 30 are disposed, for example by micro-transfer printing. FIG. 13B shows a cavity 15 in target substrate 10 with a bottom forming surface 11. As in FIG. 13A, structures 20 are disposed on bottom surface 11, for example formed by depositing materials such as organic or inorganic dielectrics (e.g., silicon dioxide or silicon nitride) and patterning the deposited materials to form the structures 20. In some embodiments, structures 20 are formed in a common step with cavity 15, for example a single pattern defines cavity 15 and structures 20 in a common step and the pattern is etched in a common single step to form both surface 11 (the cavity bottom floor) and structures 20 (“islands” that are not connected to a cavity wall, cavity side, or cavity edge) in cavity 15 using photolithographic masking, exposure, and etching to form the single pattern. Components 30 are disposed on bottom surface 11 and not on top surface 13, e.g., as shown in FIGS. 13C, 13D where target substrate 10 comprises cavity 15. Structures 20 can comprise other elements, for example one or more optical waveguides such as light pipe(s) 24. FIG. 13C illustrates structures 20 that are a part of one or more walls (e.g., edges or sides) of cavity 15 and have been patterned to form structures 20 that are not islands in cavity 15. Thus, structures 20 can be a part of target substrate 10 and extend from a bottom surface 11 of cavity 15 of target substrate 10 along an edge of cavity 15. Different structures 20 can be connected by top surface 13 of target substrate 10 Multiple components 30 can be disposed in alignment with multiple different structures 20 in a common cavity 15 (shown in the FIG. 13D but also applicable to FIG. 13B with multiple groups of structure 20 islands for each component 30). A single embodiment can comprise structures 20 that are islands and structures 20 that comprise cavity 15 walls.

Multiple structures 20 can form mechanical stops for component 30 when micro-transfer printing component 30 onto surface 11 of target substrate 10 or onto bottom surface 11 of cavity 15 in target substrate 10 by physically moving component 30 toward or against structures 20. By using multiple structures 20 with spatial gaps or spatial separations between structures 20 (rather than a single structure 20 with a single edge), broken (e.g., fractured) or separated tethers 32 of component 30 can be disposed laterally between the separated structures 20 so that tethers 32 do not form a mechanical standoff to structures 20 and do not prevent component 30 from aligning with (e.g., contacting) structures 20 when micro-transfer printing components 30 in alignment with structures 20. FIGS. 13A-13D all show tethers 32 connected to component 30 disposed laterally between structures 20 so that tethers 32 do not obstruct or prevent component 30 from contacting or coming into alignment with structures 20. Structures 20 can extend from a wall or side of cavity 15 a greater distance than tethers 32 extend from a side (e.g., edge or face) of component 30. Long and thin components 30, such as lasers, can require multiple tethers 32 along the length of components 30 to enable micro-transfer printing. Embodiments of the present disclosure illustrate methods and devices that prevent tethers 32 from inhibiting alignment between components 30 and structures 20. For example, in some embodiments, component 30 is disposed on surface 11 of target substrate 10 within one micron (e.g., within 1.0 micron, within 0.75 microns, within 0.5 microns, within 0.25 microns, or within 0.1 microns) of at least one of structures 20, of two or more of structures 20, or all of structures 20 despite the presence of one or more tethers 32 on component 30.

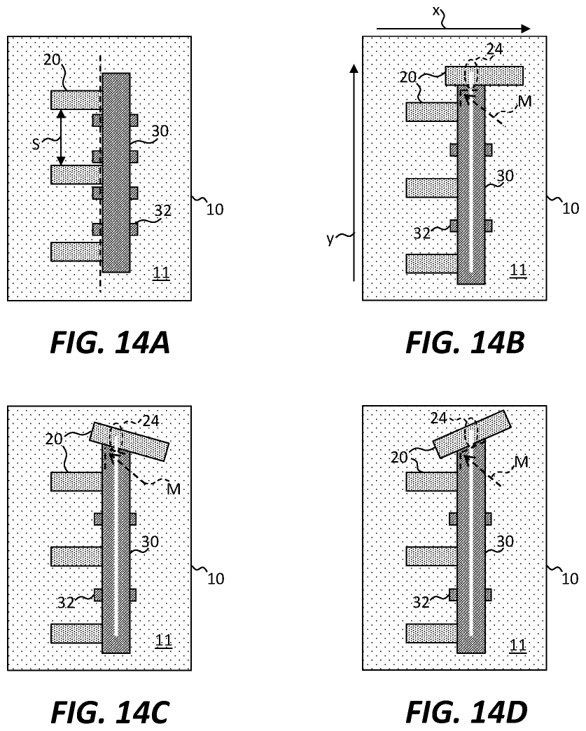

Furthermore, structure edges (or sides) of structures 20 can be arranged in a line so that a component edge (e.g., a straight edge or side) of component 30 is substantially aligned with structures 20. For example, and as shown in FIGS. 13A-13D and 14A-14D, each structure 20 of two or more of structures 20 has a structure edge (or side or wall, e.g., a sidewall) and the structure edges (sidewalls) are in a substantially straight line parallel to surface 11 of target substrate 10 or in a plane substantially orthogonal to surface 11 of target substrate 10. Components 30 are conveniently constructed with straight component edges or sides to facilitate component 30 layout and construction. Component 30 can have one or more component edges and at least one of the component edges can be substantially parallel to at least one of the structure edges. Thus, components 30 can be lined up with or along structures 20.

FIG. 14A is a top view of component 30 aligned with and having component edges parallel to structure edges of structures 20. In some embodiments and as illustrated in FIGS. 14B-14D, some of structures 20 enable alignment between component 30 and a structure 20 with an optical element, for example alignment between a micro-transfer printed optical component 30 (e.g., a laser, photo sensor, optical amplifier, or optical modulator) with a light waveguide (e.g., a light pipe 24) in structure 20. As shown in FIG. 14B, some of structures 20 are arranged in a line (e.g., have edges or sides arranged in a line, shown with a dashed line shown in FIG. 14A) and another structure 20 has an edge perpendicular to the line in alignment with component 30 so that the sides of component 30 are aligned with structures 20 in the line and a component end of component 30 is butted up against the other structure 20 so that a light-emitting or light-receiving part of component 30 can be optically aligned with light pipe 24. Component 30 can be moved horizontally in both x and y directions during micro-transfer printing (e.g., sequentially in either order or at the same time in a diagonal movement direction M as in FIG. 17A) to align component 30 with structures 20. Structures 20 are arranged so that as component 30 is moved over surface 11 structures 20 will tend to align component 30 as desired, for example by providing mechanical stops to prevent component 30 motion beyond a desired position. For example, if component 30 is rotated with respect to a desired position, structures 20 can prevent undesired rotation as component 30 moves into position. If component 30 is offset (e.g., horizontally offset in an x or y direction) with respect to a desired position, structures 20 can prevent undesired component 30 horizontal movement as component 30 moves into position in an x or y direction.

In some embodiments, structures 20 can have structure edges that are disposed at an angle of substantially ninety degrees parallel to surface 11 of target substrate 10 (e.g., orthogonal or perpendicular) as shown in FIG. 14B. In some embodiments, structures 20 can have structure edges that are disposed at an angle that is not orthogonal or perpendicular and is parallel to surface 11 of target substrate 10. For example, as shown in FIG. 14C, structures 20 have edges adjacent to component 30 that are arranged at an angle less than 90 degrees and FIG. 14D illustrates structures 20 that have edges adjacent to component 30 that are arranged at an angle greater than 90 degrees as shown with the dashed lines and arrow M (that can also indicate a direction of stamp 40 and component 30 movement for printing). Non-orthogonal angles can further physically guide component 30 into alignment with structures 20 during micro-transfer printing where component 30 has opposing component ends in a length direction that are not parallel by converting a portion of component 30 movement direction M into a vector in the desired direction.

As shown in FIGS. 14A-14D, tethers 32 are disposed along the length of component 30 and can be disposed laterally between structures 20. By separating structures 20 along component 30, structures 20 more readily guide component 30 into alignment for each structure 20 to position component 30 with respect to a desired position. To facilitate this, component 30 can be adjacent to more structures 20 along its length than along its width (e.g., is laterally adjacent to or in contact with more structures 20 along a longer side of component 30 than along a shorter side of component 30). If structures 20 were closer together, they would be less effective at accurately aligning edges of structures 20 with an edge of component 30 because the rotation of component 30 would be less controlled. Structures 20 can be made using photolithography and can, therefore, be extremely precise in size and location, for example having a size and location in contact with or within a few nanometers of a desired size and location. Thus, in embodiments of the present disclosure, structures 20 comprise a first structure 20 and a second structure 20. Component 30 can have a first component end and a second component end and first structure 20 can be disposed closer to the first component end than to the second component end and second structure 20 can be disposed closer to the second component end than to the first component end.

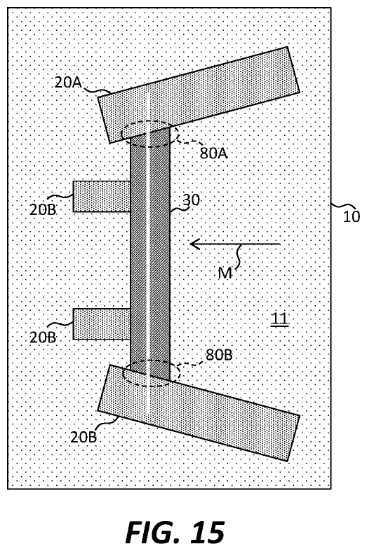

In some embodiments, and as shown in FIG. 15, structures 20 can be laterally adjacent to opposite component ends of component 30 and disposed at a non-orthogonal angle that so that as component 30 is moved horizontally, both component ends are guided into position and both opposite component ends are disposed in alignment or in contact with structures 20. The non-orthogonal angle can be open with edges that define lines parallel to surface 11 that meet on a side of structures 20 opposite component 30 and in the direction of component 30 horizontal motion. This can be useful, for example, if light pipes 24 are present in both structures 20 and optically aligned with both ends of component 30. For example, in a photonic device, component 30 can be an optical modulator or optical amplifier that inputs light from one structure 20 at one component end of component 30 and outputs modulated or amplified light at an opposite component end of component 30. Thus, in such embodiments, structures 20 comprise a first structure 20A having a first structure edge and a second structure 20B having a second structure edge, component 30 has a first component end 80A having a first component edge and an opposing second component end 80B having a second component edge. The first structure edge is at a non-orthogonal angle with respect to the second structure edge in a direction parallel to surface 11, and the first component edge is substantially parallel to the first structure edge and the second component edge is substantially parallel to the second structure edge.

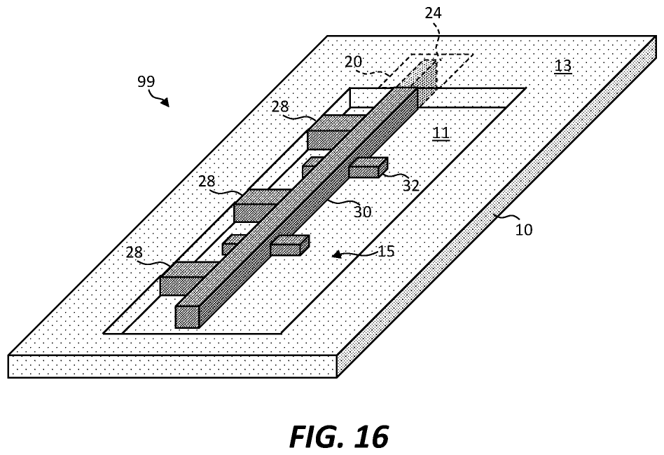

In some embodiments, and as illustrated in FIGS. 2A-2I, and 4A-15, components 30 are closely aligned with structures 20 formed on target substrate 10. Structures 20 can be substrate structures 20 and one or more sides or faces of components 30 can be in contact with or closely aligned to substrate structures 20, e.g., within one micron, 500 nm, 200 nm, or 100 nm. In some embodiments, and as shown in FIG. 16, components 30 comprise component structures 28 that extend from a side (e.g., face or edge) of component 30 and are closely aligned with or in contact with one or more substrate structures 20, for example an edge, wall, or side of a cavity 15. Thus, according to embodiments of the present disclosure, a printed structure 99 comprises a target substrate 10 and one or more substrate structures 20 extending from a surface 11 of target substrate 10. A component 30 comprising one or more component structures 28 extending from a side (e.g., edge or face) of component 30 can be disposed on surface 11. One or more component structures 28 of component 30 can be disposed in alignment with one or more substrate structures 20, for example component structures 28 can be disposed in contact with or within one micron of substrate structures 20. In some embodiments, component structures 28 and substrate structures 20 can have a same or different size and are interlaced such that one(s) of component structures 28 are disposed between one(s) of substrate structures 20 and/or one(s) of substrate structures 20 are disposed between one(s) of component structures 28 (e.g., in an alternating fashion or not). Component 30 can be non-native to target substrate 10. For example, component 30 can comprise a component substrate 38 separate and independent from target substrate 10 (e.g., as shown in FIG. 2A). Component 30 can comprise a broken (e.g., fractured) or separated tether 32.

Two or more component structures 28 can be spatially separated and broken (e.g., fractured) or separated tethers 32 (e.g., broken (e.g., fractured) or separated component tethers 32) can be disposed spatially and laterally between component structures 28 on a common side of component 30. In some embodiments, component structures 28 extend a greater distance from a side of component 30 than a broken (e.g., fractured) or separated tether 32 so that broken (e.g., fractured) or separated tethers 32 do not interfere with aligning component 30 (and component structures 28) to one or more substrate structures 20, for example by preventing component structures 28 from contacting one or more substrate structures 20.

In some embodiments, and as shown in FIG. 16, target substrate 10 comprises a cavity 15 disposed within target substrate 10. Cavity 15 can comprise a cavity bottom and cavity walls, surface 11 of target substrate 10 can be the cavity bottom, and at least one of substrate structures 20 can comprise one of the cavity walls. For example, different ones of multiple substrate structures 20 can each comprise a different one of the cavity walls.

Aligning components 30 with structures 20 is very useful for photonic systems, for example comprising laser, light emitters such as diodes, waveguides (light pipes 24), optical amplifiers, and optical modulators. Optical components 30 are often constructed in or on relatively expensive compound semiconductor material wafers rather than relatively inexpensive glass, polymer, or silicon substrates. Moreover, silicon substrates can comprise light pipes 24 (e.g., made with patterned silicon nitride on the silicon substrate) and control circuits for controlling compound semiconductor components 30 in a photonic integrated circuit (e.g., a photonic system). Printed structures 99 of the present disclosure can be photonic structures, devices, or systems. Components 30 that are optically aligned with [e.g., due to close spatial proximity (e.g., within five microns, within two microns, within one micron)] light pipes 24 in structures 20 have improved light coupling from component 30 to light pipe 24 (or vice versa) and better optical system performance. Alignment between components 30 and one or more structures 20 can include both a close distance in any of three spatial dimensions (or a combination thereof) and a horizontal rotation to improve light coupling between optical components 30 and one or more light pipe(s) 24 in one or more structures 20.

According to some embodiments of the present disclosure, an adhesive 12 (adhesive layer 12) such as an epoxy or resin is disposed on surface 11 of target substrate 10, for example by spray or spin coating. Adhesive 12 can be disposed between component 30 and surface 11 to adhere component 30 to surface 11 and thereby facilitate micro-transfer printing component 30 onto surface 11 and prevent component 30 from moving with respect to surface 11 and structures 20 when subject to mechanical or thermal stress. In some embodiments, component 30 is contacted to adhesive 12 and then moved at least partially horizontally (e.g., in the x direction) as illustrated in FIG. 20. Adhesive 12 can be pushed by component 30 into a location directly between component 30 and structure 20 and form a bulge or protrusion of adhesive 12 in a vertical direction preventing component 30 from moving into alignment (e.g., contact with) structure 20. Adhesive 12 can be a curable adhesive 12.

To mitigate or prevent adhesive 12 from pushing, bulging, or piling up between component 30 and structure 20 during micro-transfer printing, structures 20 can be arranged or constructed as shown in FIGS. 13A-16. In these Figures, structures 20 are separated and independent so that adhesive 12 can move laterally into spaces between structures 20. In arrangements where structures 20 are desired to form an angle into which component 30 is disposed, structures 20 can be separated to form a gap 22 between structures 20 and component 30 into which adhesive 12 can be pushed to prevent adhesive 12 from piling up directly between components 30 and structures 20. As shown in FIG. 21A to 21D, a gap 22 is located between structures 20 with structure edges at an angle to each other shown by the dashed lines and arrow, for example at 90 degrees (as shown in FIGS. 21B and 21C), at less than 90 degrees (as shown in FIG. 21A) or at greater than 90 degrees (as shown in FIG. 21D). FIG. 21B illustrates embodiments in which component 30 has a cutoff portion forming gap 22 into which adhesive 12 can be pushed by a horizontal motion of component 30 in contact with adhesive 12. Moreover, because photolithographic methods and materials do not form perfectly square corners, a rounded interior corner of structure 20 can inhibit a corresponding corner of component 30 from approaching structure 20 closely, as shown in FIG. 21C. The cut-off corner of component 30 can also mitigate that problem by providing a similarly rounded (or cut-off) component 30 corner complementing a rounded interior corner of structure 20, e.g., FIGS. 21B and 21C can be used together. Thus, FIG. 21C illustrates embodiments in which structure 20 has an intrusion or indentation forming gap 22 into which adhesive 12 can be pushed by a horizontal motion of component 30 in contact with adhesive 12. Gap 22 can also enable an exterior corner of component 30 to closely approach and align with an interior corner of structure 20 where structure 20 has rounded interior corners as in FIG. 21B. An exterior corner of component 30 can extend into gap 22 to enable alignment between component 30 edges and structure 20 edges. Because component 30 can horizontally push adhesive 12 into gap 22, in some embodiments, adhesive 12 is thicker in gap 22 than between component 30 and surface 11 of target substrate 10 or between component 30 and at least one of the edges of a structure 20 as a consequence of pushing adhesive 12 along surface 11 into gap 22, thereby preventing or reducing any bulging, piling up, or protuberance of adhesive 12 over surface 11 and facilitating alignment between component 30 and a structure 20 by disposing excess adhesive 12 in gap 22 rather than between component 30 and structure 20.

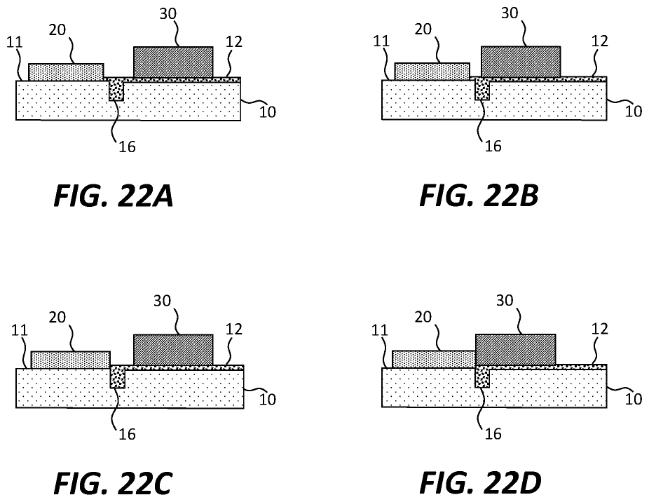

In some embodiments and as illustrated in FIGS. 22A-22D, excess adhesive 12 can be pushed into a gutter 16 (a trench 16) in target substrate 10 (e.g., extending from substrate surface 11 into target substrate 10) disposed laterally between component 30 and structure 20, beneath component 30 where component 30 is disposed at least partially over gutter 16, or both. As used herein, gutter 16 is used synonymously with trench 16. Gutter 16 can be laterally adjacent to structure 20 or component 30, or both. As shown in FIGS. 22A-22C, gutter 16 can be disposed at least partly laterally between component 30 and structure 20. In FIGS. 22B and 22D, gutter 16 is also disposed at least partly directly beneath component 30 (component 30 is also disposed at least partly over (e.g., on) gutter 16). In FIG. 22D, gutter 16 is disposed entirely beneath component 30 (so that component 30 covers gutter 16). As shown in FIGS. 22A and 22B, structure 20 can be disposed a distance away from an edge of gutter 16, for example one to five microns away. As shown in FIGS. 22C and 22D, structure 20 can be disposed at an edge of gutter 16. As shown in FIGS. 22A and 22C, component 30 is not disposed over gutter 16. As shown in FIG. 22B, gutter 16 can be disposed at least partly beneath component 30. As shown in FIG. 22D, gutter 16 can be disposed entirely beneath component 30. In FIGS. 22A-22D, gutter 16 is at least partially filled but need not be completely filled with adhesive 12, for example partially as a result of lateral translation of component 30 over target substrate 10 during printing (e.g., in order to bring component 30 in alignment with structure 20 as shown).

It can be difficult to provide a layer of adhesive 12 that has a constant thickness and, because of capillary effects or because of spin coating non-uniformity due to topographic structures (e.g., structures 20), adhesive 12 can be thicker adjacent to structures 20, thereby making close and accurate alignment between component 30 and structure 20 difficult. The presence of gutter 16 adjacent to (e.g., close to or at an edge of) structure 20, beneath structure 20, or both adjacent to and beneath structure 20 can mitigate the thicker adhesive 12 so that component 30 and structure 20 can be aligned. Moreover, if horizontal movement of component 30 toward structure 20 in contact with adhesive 12 pushes adhesive 12 toward structure 20 and inhibits alignment between component 30 and structure 20, rather than piling up adhesive 12 between component 30 and structure 20, excess adhesive 12 can move into gutter 16, enabling alignment between component 30 and structure 20.

Thus, according to embodiments of the present disclosure, a printed structure 99 can comprise a target substrate 10, a structure 20 extending from a surface 11 of target substrate 10, a component 30 disposed in alignment with structure 20 (e.g., and comprising a component substrate separate and independent from target substrate 10 and/or a broken or separated tether 32 as a consequence of micro-transfer printing component 30 onto or over surface 11), and a gutter 16 formed in target substrate 10 between component 30 and structure 20 or beneath component 30, or both between component 30 and structure 20 and beneath component 30 (e.g., where component 30 overlaps a portion of, but not all of, gutter 16). Adhesive 12 can be disposed in gutter 16 and between component 30 and surface 11. Adhesive 12 in gutter 16 can be thicker than adhesive 12 between component 30 and surface 11 or between component 30 and structure 20, for example because adhesive 12 can be pushed into gutter 16 by component 30. Gutter 16 can surround structures 20, for example where structures 20 form islands on surface 11 or can be disposed along exposed edges of structures 20, for example where structures 20 comprise edges, faces, or walls of cavity 15.

In some embodiments, a printed structure 99 comprises a target substrate 10 having a substrate surface 11, a gutter 16 disposed in target substrate 10, an adhesive 12 disposed on target substrate 10 and at least partially in gutter 16, and a component 30 printed onto substrate surface 11 adjacent to or at least partially over gutter 16. Adjacent can mean within ten, five, two, one, or one half microns on surface 11. Component 30 can comprise a broken (e.g., fractured) or separated tether 32. In some embodiments, printed structure 99 comprises substrate structure 20 extending from substrate surface 11 adjacent to gutter 16. Extending from can mean upward in a direction away from target substrate 10. In some embodiments, gutter 16 is at least partially laterally between printed component 16 and substrate structure 20. In some embodiments, printed component 30 is in contact with substrate structure 20 and gutter 16 is beneath component 30 (e.g., in a direction toward target substrate 10 from component 30.

To facilitate micro-transfer printing, component 30 can have a thickness greater than a thickness of structures 20 (e.g., component 30 extends a greater vertical distance from surface 11 than structures 20) so that a micro-transfer printing device (e.g., a stamp or stamp post) does not contact structures 20 during transfer.

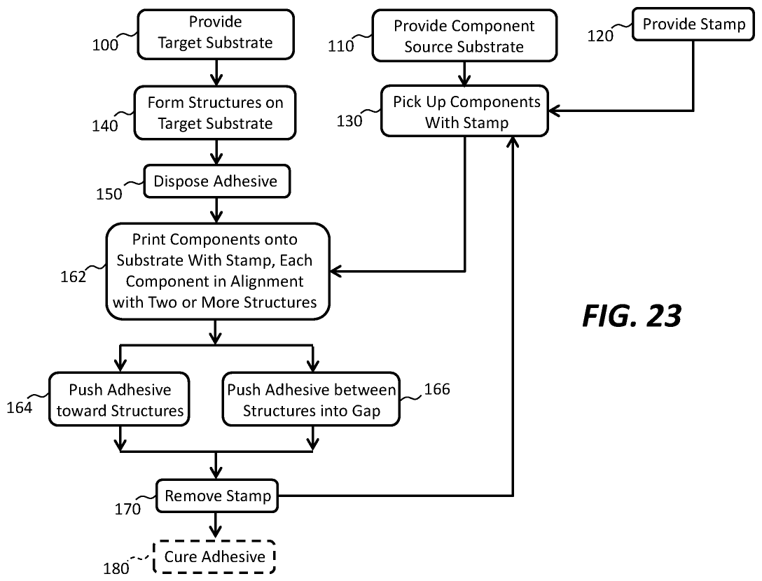

According to embodiments of the present disclosure and as illustrated in FIG. 23, a method of making a printed structure 99 can comprise providing a target substrate 10 in step 100 and providing two or more structures 20 extending from a surface 11 of target substrate 10 in step 140. Structures 20 are spatially separated independent structures that are not in direction contact. A component source wafer with components 30 each having a substrate separate and independent from target substrate 10 is provided in step 110 and a transfer element (e.g., a transfer device such as a stamp for micro-transfer printing components 30) provided in step 120. Adhesive 12 is coated on surface 11 of target substrate 10 in step 150, for example by spray, curtain, or spin coating, and components 30 are picked up with the stamp in step 130 so that component 30 is adhered to the transfer element. Using the stamp, component 30 is micro-transfer printed onto surface 11 of target substrate 10 in alignment with one or more (e.g., two) structures 20 in step 162 by moving the transfer element with the adhered component 30 vertically toward surface 11 of target substrate 10 and horizontally towards the one or more structures 20 at least until component 30 physically contacts structure 20 or is adhered to surface 11 of target substrate 10, thereby pushing at least a portion of adhesive 12 with component 30 laterally toward structures 20 in step 164 and into a gap 22 between structures 20 in step 166, and separating the transfer element from component 30 in step 170. Adhesive 12 can be cured in step 180 if it is a curable adhesive 12.

In some embodiments, the two or more structures 20 comprise structure edges forming an angle defined by lines extending along the structure edges parallel to surface 11 of target substrate 10 and methods of the present disclosure comprise pushing the portion of adhesive 12 between structures 20 toward an intersection of the lines as shown in FIGS. 14D and 21D. In some embodiments, component 30 comprises a cut-off corner forming a gap 22 and methods comprise pushing adhesive 12 into the cut-off corner, as shown in FIG. 2021B. In some embodiments, structure 20 comprises an indentation or inclusion forming a gap 22 and component 30 pushes adhesive 12 into the indentation or inclusion, as shown in FIG. 21C.

In some embodiments, the two or more spatially separated structures 20 are separated by a separation distance S (shown in FIG. 14A) and the transfer element moves the adhered component 30 horizontally towards one of the structures 20 a shear distance less than separation distance S in a direction separating structures 20, for example as illustrated by the arrow in FIG. 14A. By moving component 30 a distance less than separation distance S in a direction separating structures 20, tethers 32 are less likely to strike structures 20 and inhibit alignment between structures 20 and component 30.

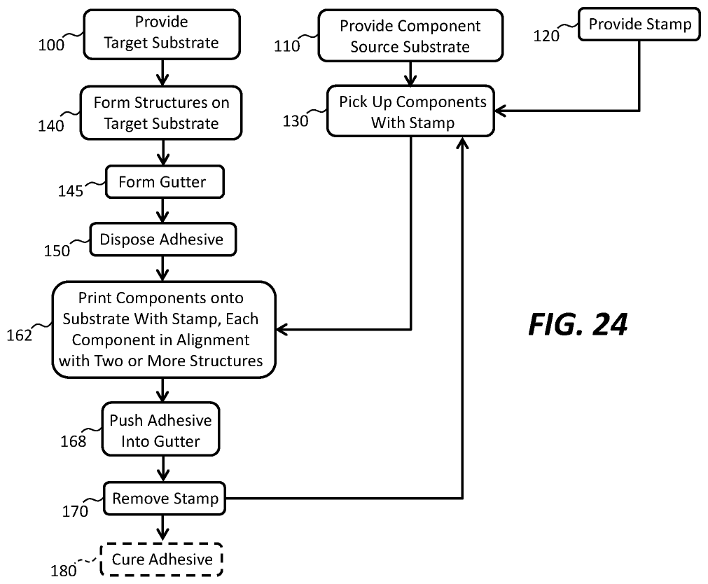

According to methods of the present disclosure as shown in FIG. 24, gutters 16 are formed in step 145 in a different or the same step as forming structures 20. As components 30 push adhesive 12 laterally along surface 11 as the stamp moves component 30 horizontally along surface 11 toward structure 20, the pushed portion (e.g., excessive amount) of adhesive 12 can flow into gutter 16 in step 168, removing it from directly between component 30 and structure 20.

By using devices, system, and methods of the present disclosure, some embodiments have been constructed and demonstrated comprising component 30 disposed on surface 11 of target substrate 10 within one micron (e.g., within 1.0 micron, within 0.75 microns, within 0.5 microns, within 0.25 microns, or within 0.1 microns) of or in contact with at least one of structures 20, of two or more of structures 20, or of all of structures 20. Some constructions have disposed a micro-laser component 30 in alignment with four structures 20 along the length of the micro-laser in cavity 15 of a silicon target substrate 10. The micro-laser (component 30) has an angled component end (e.g., as shown in FIGS. 14D) and gutters 16 are disposed entirely around each structure 20 within cavity 15 and along the edge of the structure 20. A light pipe 24 comprising silicon nitride is disposed on top surface 13 of target substrate 10 in alignment with the micro-laser (component 30).

In some demonstrations, gutter 16 was 3 microns deep, adhesive 12 was spin coated on surface 11 at 70-100 nm depth but, because of surface 11 topography (e.g., gutter 16, structures 20, and cavity 15 was 30-70 nm deep within gutter 16. Alignment distance in both x and y directions was less than 500 nm (in some cases less than 100 nm) and component 30 was in contact with structures 20 along the length of component 30. In some embodiments, the cavity wall (which can be a substrate structure 20) has a height of approximately 4 microns, 3-5 microns, 5-10 microns, or 10-20 microns, from surface 11. Component 30 was a micro-laser with a width in the shorter, width direction of 60 microns and a length in the longer, length direction of 550 microns, with an angled component end. A light pipe 24 was formed in a structure 20 in alignment with (e.g., close and oriented to receive light from) the micro-laser (component 30).

In some embodiments of the present disclosure, to allow adhesive 12 to effectively flow into gutter 16, gutter 16 can have a depth no less than a thickness of adhesive 12 on surface 11 or between component 30 and surface 11, no less than two times the thickness of adhesive 12 on surface 11 or between component 30 and surface 11, no less than five times the thickness of adhesive 12 on surface 11 or between component 30 and surface 11, no less than ten times the thickness of adhesive 12 on surface 11 or between component 30 and surface 11, no less than twenty times the thickness of adhesive 12 on surface 11 or between component 30 and surface 11, no less than fifty times the thickness of adhesive 12 on surface 11, or no less than 100 times the thickness of adhesive 12 on surface 11 or between component 30 and surface 11. In some embodiments, gutter 16 has a depth no less than 500 nm, no less than one micron, no less than two microns, or no less than three microns.

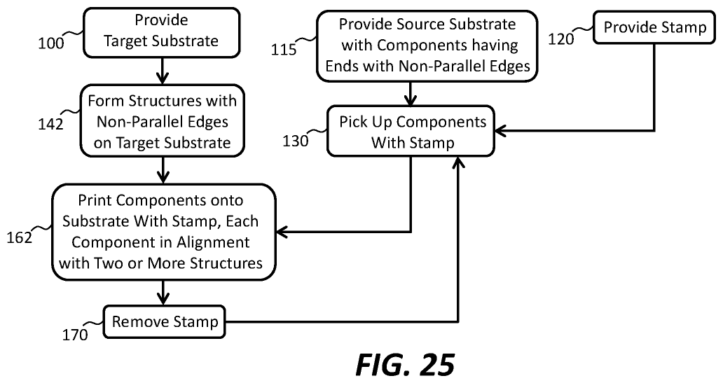

As noted, component ends with angled edges can be aligned with structures 20 having non-orthogonal edges (e.g., as shown in FIGS. 14C, 14D, 21A, 21D. In some embodiments and as illustrated in FIG. 25, methods of the present disclosure comprise forming (or providing) structures 20 with non-parallel edges on surface 11 of target substrate 10 in step 142 and providing a component source substrate with components 30 having component ends with non-parallel edges in step 115. Component 30 is micro-transfer printed onto surface 11 and moved horizontally (e.g., moving vertically and horizontally in x or y direction in any order) along surface 11 to align the component edges with the structure edges, e.g., so that the component edges of the component ends are aligned with and substantially parallel to the structure edges in step 162. The arrow (movement direction M) in FIG. 15 illustrates the direction of motion, e.g., component 30 can be moved horizontally in a direction mostly or substantially orthogonal to the long side (e.g., the length) of component 30. Embodiments of FIGS. 15 and 21 can performed without adhesive 12 (as illustrated in FIGS. 10-11C) or with adhesive 12 as illustrated in FIG. 20. Where not specifically recited in FIGS. 24 and 25, the steps illustrated are similar to or the same as those steps described with respect to FIG. 23, and vice versa.

Embodiments of the present disclosure have been constructed and successfully operated, for example in a target substrate 10 with a gutter 16 adjacent to a substrate structure 20. A laser component 30 has been successfully micro-transfer printed onto a target substrate 10 adjacent to substrate structures 20 surrounded by one or more gutters 16 in alignment with one or more light pipes 24.

Adhesive 12 is described in various embodiments as being, inter alia, adjacent to gutter 16, adjacent to structure 20, on target substrate 10, beneath component 30, between component 30 and target substrate 10, and between structure 20 and target substrate 10. It should be understood that unless accompanied by the word “solely” or “exclusively” or a similar word, at least a portion of adhesive 12 can be disposed as described while a portion, or in some embodiments none, of adhesive 12 is disposed elsewhere. For example, when adhesive 12 is described as being disposed between component 30 and target substrate 10, it should be understood that some of adhesive 12 can be, but is not necessarily, disposed on target substrate 10 and not between component 30 and target substrate 10 (e.g., adhesive 12 extends along target substrate 10 beyond a perimeter of component 30 in at least one direction). Similarly, in some embodiments, adhesive 12 disposed adjacent to gutter 16 means that adhesive 12 is disposed along (e.g., within 5 microns) at least one edge of gutter 16 though adhesive 12 can extend along target substrate 10 elsewhere (e.g., between component 30 and target substrate 10, beneath). For embodiments described that include adhesive 12 and where the word “solely” or “exclusively” or a similar word was not used in such description, additional analogous embodiments where adhesive 12 is disposed solely/exclusively as described (e.g., between component 30 and target substrate 10) are also contemplated. (Solely and exclusively are used interchangeably in this context with respect to adhesive 12.) In some embodiments, vertical alignment between component 30 and one or more structures 20 can be improved by providing one or more gutters 16, for example by allowing a thinner and/or more consistent thickness layer of adhesive 12 to be used, where excess adhesive 12 is displaced (e.g., pushed) into the one or more gutters 16.

Structure 20 can be native or non-native to target substrate 10. Structures 20 can include a combination of both one or more native structure 20 and one or more non-native structures 20. In some embodiments, each of one or more structures 20 defines an island on target substrate 10. An island structure 20 can be formed by patterned etching of target substrate 10 or growth (e.g., epitaxial growth) of material on target substrate 10. Structures 20 can be formed simultaneously with formation of cavity 15 in target substrate 10, for example in the same patterned etching of target substrate 10. One or more structures 20 can extend from a wall of cavity 15 in target substrate 10, regardless of whether such structure(s) 20 are native or non-native to target substrate 10. One or more structures 20 can form a continuous structure a portion of target substrate 10, for example be lateral protrusion(s) from a wall of cavity 15. Such lateral protrusion(s) can, but need not necessarily, terminate in a same plane. A combination of one or more island structures 20 and one or more protrusion structures 20 can be used in some embodiments. Multiple structures 20 can exist as part of a larger common structure, for example where the larger common structure has a complex geometry including multiple lateral protrusions. Such larger common structures can be part of a cavity 15 or can be separate structures (e.g., regardless of whether any cavity 15 is present or not).

In some embodiments, component 30 or structure 20 is adjacent to gutter 16. In some embodiments, component 30 or structure 20 that is adjacent to gutter 16 is disposed within five microns, within two microns, within one micron, within 1.0 micron, or within 0.5 microns of gutter 16, for example component 30 or structure 20 can partially overlap gutter 16. In some embodiments, when component 30 is aligned with gutter 16, component 30 disposed within 5 microns, within 2 microns, within 1 micron, within 1.0 microns, or within 0.5 microns of gutter 16.

Component 30 that is disposed in alignment with (e.g., are aligned to or aligned with) one or more structures 20 can be disposed within five microns, within two microns, within one micron, within 1.0 microns, or within 0.5 microns of each of one or more structures 20. In some embodiments, a face of component 30 can be within ±10 degrees (e.g., within ±8 degrees, within ±6 degrees, within ±4 degrees, or within ±2 degrees) of parallel to a face of structure 20 when component 30 is aligned with structure 20. In some embodiments, component 30 is aligned with one or more structures 20 in that component 30 is disposed in optical alignment with one or more structures 20, for example when component 30 is an optical component and structure 20 includes one or more optical elements, such as a waveguide, optical amplifier, optical modulator, or combination thereof (such that structure 20 is itself an optical component). When component 30 and one or more structures 20 are optically aligned, light from component 30 can be received by (e.g., and processed by) one or more optical elements in structure(s) 20. Printing component 30 to target substrate 10 by contacting component 30 to one or more structures 20 during printing aligns component 30 with one or more structures 20. Component 30 will not necessarily physically contact each of one or more structures 20 after printing, for example each of one or more structures 20 can be separated from component 30 by a small distance of no more than one micron. In some embodiments, printed structure 99 is designed to have component 30 be disposed in a certain location relative to one or more structures 20 such that component 30 is then considered aligned with one or more structures 20 when disposed within a certain tolerance (e.g., no more than five microns, no more than two microns, no more than one micron, no more than 1.0 micron, or no more than 0.5 microns) of the certain location; such one or more structures 20 can facilitate such disposition, for example during printing. In some embodiments, component 30 is disposed at the certain location to within manufacturing (e.g., printing) tolerances. FIGS. 13A-16, among others, illustrate components 30 aligned with structures 20.

Reference is made throughout the present description to examples of printing that are micro-transfer printing with stamp 40 comprising stamp post 42 when describing certain examples of printing components 30 (e.g., in describing FIGS. 2A-2I). Similar other embodiments are expressly contemplated where a transfer element 40 that is not a stamp is used to similarly print components 30. For example, in some embodiments, a transfer element 40 that is a vacuum-based, magnetic, or electrostatic transfer element 40 can be used to print components 30. A component 30 can be adhered to a transfer element 40 with any type of force sufficient to maintain contact between the component 30 and transfer element 40 when desired and separate transfer element 40 from component 30 when desired. For example, component 30 can be adhered to transfer element 40 with one or more of an adhesion, electrostatic, van der Waals, magnetic, or vacuum force. In some embodiments, adhesion between component 30 and transfer element 40 occurs at least in part due to a force generated by operating transfer element 40 (e.g., an electrostatic force) and separation of transfer element 40 from component 30 occurs at least in part by ceasing provision of the force (e.g., an electrostatic force). Similar transfer elements 40 can be used to print structures 20. A vacuum-based, magnetic, or electrostatic transfer element 40 can comprise a plurality of transfer posts, each transfer post being constructed and arranged to pick up a single component 30 (similarly to stamp posts 42 in stamp 40).

According to some embodiments, micro-transfer printing can include any method of transferring components 30 from a component source wafer (e.g., a native source wafer) to a target substrate 10 by contacting components 30 on the component source wafer with a patterned or unpatterned stamp surface of a stamp 40 (e.g., a distal end of stamp post 42), removing (e.g., separating) components 30 from the component source wafer, transferring stamp 40 and contacted components 30 to target substrate 10, and contacting components 30 to a surface 11 of target substrate 10, for example adhesive layer 12 by moving stamp 40 or target substrate 10. Components 30 can be adhered to stamp 40 or target substrate 10 by, for example, van der Waals forces, electrostatic forces, magnetic forces, chemical forces, adhesives, or any combination of the above. In some embodiments, components 30 are adhered to stamp 40 with separation-rate-dependent adhesion, for example kinetic control of viscoelastic stamp materials such as can be found in elastomeric transfer elements or transfer devices such as a PDMS stamp 40. Stamps 40 can be patterned or unpatterned and can comprise stamp posts 42 having a stamp post area on the distal end of stamp posts 42. Stamp posts 42 can have a length, a width, or both a length and a width, similar or substantially equal to a length, a width, or both a length and a width of component 30.

In exemplary methods, a viscoelastic elastomer (e.g., PDMS) stamp 40 (e.g., comprising a plurality of stamp posts 42) is constructed and arranged to retrieve and transfer arrays of components 30 from their native component source wafer onto non-native patterned target substrates 10. In some embodiments, stamp 40 mounts onto motion-plus-optics machinery (e.g., an opto-mechatronic motion platform) that can precisely control stamp 40 alignment and kinetics with respect to both component source wafers and target substrates 10. During micro-transfer printing, the motion platform brings stamp 40 into contact with components 30 on the component source wafer, with optical alignment performed before contact. Rapid upward movement of the print-head (or, in some embodiments, downward movement of the component source wafer) breaks (e.g., fractures) or separates tether(s) 32 forming broken (e.g., fractured) or separated tethers 32, transferring component(s) 30 from native component source wafer to stamp 40 or stamp posts 42. Stamp 40 populated with components 30 then travels to patterned target substrate 10 (or vice versa) and one or more components 30 are then aligned to target substrate 10 and printed (for example as described in relation to FIGS. 1 and 2A-2H).

A component source wafer can be any source wafer or substrate with (e.g., native) transfer-printable components 30 that can be transferred with a transfer element 40 (e.g., a stamp 40). For example, a component source wafer can be or comprise a semiconductor (e.g., silicon) in a crystalline or non-crystalline form, a compound semiconductor (e.g., comprising GaN or GaAs), a glass, a polymer, a sapphire, or a quartz wafer. Sacrificial portions of native component source wafer enabling the release of components 30, for example by etching, can be formed of a patterned oxide (e.g., silicon dioxide) or nitride (e.g., silicon nitride) layer or can be an anisotropically etchable portion of a sacrificial layer of a component source wafer over which components 30 are disposed while also physically connected by tether 32 to an anchor of the component source wafer. Typically, component source wafers are smaller than patterned target substrates 10 and can have a higher density of components 30 disposed thereon than components 30 disposed on target substrate 10.

Components 30 can be any transfer-printable element, for example including any one or more of a wide variety of active or passive (or active and passive) components 30 (e.g., devices or subcomponents). Components 30 can be any one or more of integrated devices, integrated circuits (such as CMOS circuits), light-emitting diodes, photodiodes, sensors, electrical or electronic devices, optical devices, opto-electronic devices, magnetic devices, magneto-optic devices, magneto-electronic devices, and piezo-electric device, materials or structures. Components 30 can comprise electronic component circuits electrically connected to electrodes 72 that operate component 30. Component 30 can be responsive to electrical energy, to optical energy, to electromagnetic energy, or to mechanical energy, or a combination thereof, for example. In some embodiments, an electro-optic device comprises component 30 (e.g., and, optionally, structure 20). In some embodiments, components 30 are light emitters, for example are one or more of light-emitting diodes, lasers, diode lasers, vertical-cavity surface-emitting lasers, micro-lasers, micro-light-emitting diodes, organic light-emitting diodes, inorganic light-emitting diodes, quantum-dot based light emitters, and super-luminescent diodes.

Components 30 formed or disposed in or on component source wafers can be constructed using integrated circuit, micro-electro-mechanical, or photolithographic methods for example. Components 30 can comprise one or more different component materials, for example non-crystalline (e.g., amorphous), polycrystalline, or crystalline semiconductor materials such as silicon or compound semiconductor materials or non-crystalline or crystalline piezo-electric materials. In some embodiments, component 30 comprises a layer of dielectric material, for example an oxide or nitride such as silicon dioxide or silicon nitride.

In certain embodiments, components 30 can be native to and formed on sacrificial portions of component source wafers and can include seed layers for constructing crystalline layers on or in component source wafers. Components 30, sacrificial portions, anchors, and tethers 32 can be constructed, for example using photolithographic processes. Components 30 can be micro-devices having at least one of a length and a width less than or equal to 200 microns, e.g., less than or equal to 100 microns, less than or equal to 50 microns, less than or equal to 25 microns, less than or equal to 15 microns, less than or equal to 10 microns, or less than or equal to five microns, and alternatively or additionally a thickness of less than or equal to 50 microns, e.g., less than or equal to 25 microns, less than or equal to 15 microns, less than or equal to 10 microns, less than or equal to five microns, less than or equal to two microns, or less than or equal to one micron. Components 30 can be unpackaged dice (each an unpackaged die) that, in some embodiments, are transferred directly from one or more (e.g., native) component source wafers on or in which components 30 are constructed to target substrate 10. Anchors and tethers 32 can each be or can comprise portions of a native component source wafer that are not sacrificial portions and can include layers formed on component source wafers, for example dielectric or metal layers and for example layers formed as a part of photolithographic processes used to construct or encapsulate components 30.

Target substrate 10 can be any destination substrate or target substrate to which components 30 are transferred (e.g., micro-transfer printed), for example flat-panel display substrates, printed circuit boards, or similar substrates can be used in various embodiments. Target substrates 10 can be, for example substrates comprising one or more of glass, polymer, quartz, ceramics, metal, and sapphire. Target substrates 10 can be semiconductor substrates (for example silicon) or compound semiconductor substrates. In some embodiments, target substrate 10 is a semiconductor substrate and comprises an electronic substrate circuit. Electronic substrate circuits can be electrically connected through electrodes 72 to control, provide signals to, or respond to component 30.

In some embodiments, a layer 12 of adhesive, such as a layer of resin, polymer, or epoxy, either curable or non-curable, adheres components 30 onto target substrate 10 and can be disposed, for example by coating or lamination. In some embodiments, an adhesive layer 12 is disposed in a pattern, for example disposed in locations on target substrate 10 where components 30 are to be printed (e.g., micro-transfer printed). A layer of adhesive can be disposed using inkjet, screening, or photolithographic techniques, for example. In some embodiments, adhesive layer 12 is coated, for example with a spray or slot coater, and then patterned, for example using photolithographic techniques. If an adhesive 12 is disposed over at least a portion of surface 11 of target substrate 10, a component 30 disposed on adhesive 12 is also said to be disposed on surface 11 of target substrate 10. In some embodiments, structures 20 are disposed on an adhesive 12. In some embodiments, components 30 are disposed on an adhesive 12. In some embodiments, both components 30 and structures 20 are disposed on an adhesive 12 (e.g., a common adhesive layer 12).

Patterned electrical conductors (e.g., wires, traces, or electrodes such as electrical substrate contact pads 14 found on printed circuit boards, flat-panel display substrates, and in thin-film circuits) can be formed on any combination of components 30, structures 20, and target substrate 10, and any one can comprise electrical conductors such as wires or electrical contact pads that electrically connect to components 30 or structures 20. Such patterned electrical conductors and electrodes (e.g., contact pads) can comprise, for example, metal, transparent conductive oxides, or cured conductive inks and can be constructed using photolithographic methods and materials, for example metals such as aluminum, gold, or silver deposited by evaporation and patterned using pattern-wise exposed, cured, and etched photoresists, or constructed using imprinting methods and materials or inkjet printers and materials, for example comprising cured conductive inks deposited on a surface 11 or provided in micro-channels in or on target substrate 10.

Gutter 16, where present, can be formed in target substrate 10 in any suitable fashion. In some embodiments, gutter 16 is formed by photolithographic patterning (e.g., of an original flat substrate). In some embodiments, gutter 16 is formed by patternwise etching of target substrate 10. In some embodiments, gutter 16 is formed by focused ablation (e.g., laser ablation). In some embodiments, gutter 16 is formed in target substrate 10 by patternwise depositing a layer of material on target substrate 10 that defines gutter 16 by where material is not deposited, where the layer of material defines substrate surface 11. Such deposition can happen by photolithographic processing or other means, such as slot-die coating, inkjet printing, or other related techniques.

Examples of micro-transfer printing processes suitable for disposing components 30 onto target substrates 10 are described in Inorganic light-emitting diode displays using micro-transfer printing (Journal of the Society for Information Display, 2017, DOI #10.1002/jsid.610, 1071-0922/17/2510-0610, pages 589-609), U.S. Pat. No. 8,722,458 entitled Optical Systems Fabricated by Printing-Based Assembly, U.S. Pat. No. 10,103,069 entitled Pressure Activated Electrical Interconnection by Micro-Transfer Printing, U.S. Pat. No. 8,889,485 entitled Methods for Surface Attachment of Flipped Active Components, U.S. patent application Ser. No. 14/822,864 entitled Chiplets with Connection Posts, U.S. Pat. No. 10,224,460 entitled Micro Assembled LED Displays and Lighting Elements, and U.S. Pat. No. 10,153,256, entitled Micro-Transfer Printable LED Component, the disclosure of each of which is incorporated herein by reference in its entirety.

For a discussion of various micro-transfer printing techniques, see also U.S. Pat. Nos. 7,622,367 and 8,506,867, each of which is hereby incorporated by reference in its entirety. Micro-transfer printing using compound micro-assembly structures and methods can also be used in certain embodiments, for example, as described in U.S. patent application Ser. No. 14/822,868, filed Aug. 10, 2015, entitled Compound Micro-Assembly Strategies and Devices, which is hereby also incorporated by reference in its entirety. In some embodiments, any one or more of component 30, structure 20, and printed structure 99 is a compound micro-assembled structure (e.g., a compound micro-assembled macro-system).

According to various embodiments, a component source wafer (e.g., a native component source wafer) can be provided with components 30, patterned sacrificial portions, tethers 32, and anchors already formed, or they can be constructed as part of a method in accordance with certain embodiments. Component source wafers and components 30, transfer element 40 (e.g., a stamp 40), and target substrate 10 can be made separately and at different times or in different temporal orders or locations and provided in various process states.

The spatial distribution of any one or more of components 30 and structures 20 is a matter of design choice for the end product desired. In some embodiments, all components 30 in an array on a component source wafer are transferred to a transfer element 40. In some embodiments, a subset of components 30 in an array on a native component source wafer is transferred. By varying the number and arrangement of stamp posts 42 on transfer stamps 40, the distribution of components 30 on stamp posts 42 of transfer stamp 40 can be likewise varied, as can the distribution of components 30 and structures 20 on target substrate 10.

Structures 20 can be disposed in an array on target substrate 10. For example, structures 20 can be disposed by printing (e.g., micro-transfer printing) them onto target substrate 10. Structures 20 can be disposed in a regular array. Structures 20 can be disposed in an array having a linear density in one or two dimensions. The linear density can be, for example, no more than 200 structures 20 per mm and/or no less than 0.1 structure 20 per mm. Components 30 can be disposed in an array (e.g., a regular array) that corresponds to the array (e.g., regular array) in which structures 20 are disposed. Because components 30, in certain embodiments, can be made using integrated circuit photolithographic techniques having a relatively high resolution and cost and target substrate 10, for example a printed circuit board, can be made using printed circuit board techniques having a relatively low resolution and cost, electrical conductors (e.g., electrodes 72) can be much larger than electrical contacts or component electrodes on component 30, thereby reducing manufacturing costs. For example, in certain embodiments, printable component 30 has at least one of a width, length, and height from 0.5 μm to 200 μm (e.g., 0.5 to 2 μm, 2 to 5 μm, 5 to 10 μm, 10 to 20 μm, 20 to 50 μm, or 50 to 100 μm, or 100 to 200 μm).

In certain embodiments, target substrate 10 is or comprises a member selected from the group consisting of polymer (e.g., plastic, polyimide, PEN, or PET), resin, metal (e.g., metal foil) glass, a semiconductor, and sapphire. In certain embodiments, a target substrate 10 has a thickness from 5 microns to 20 mm (e.g., 5 to 10 microns, 10 to 50 microns, 50 to 100 microns, 100 to 200 microns, 200 to 500 microns, 500 microns to 0.5 mm, 0.5 to 1 mm, 1 mm to 5 mm, 5 mm to 10 mm, or 10 mm to 20 mm).

Components 30, in certain embodiments, can be constructed using foundry fabrication processes used in the art. Layers of materials can be used, including materials such as metals, oxides, nitrides and other materials used in the integrated-circuit art. Each component 30 can be or include a complete semiconductor integrated circuit and can include, for example, any combination of one or more of a transistor, a diode, a light-emitting diode, and a sensor. Components 30 can have different sizes, for example, at least 100 square microns (e.g., at least 1,000 square microns, at least 10,000 square microns, at least 100,000 square microns, or at least 1 square mm). Alternatively or additionally, components 30 can be no more than 100 square microns (e.g., no more than 1,000 square microns, no more than 10,000 square microns, no more than 100,000 square microns, or no more than 1 square mm). Components 30 can have variable aspect ratios, for example from 1:1 to 10:1 (e.g., 1:1, 2:1, 5:1, or 10:1). Components 30 can be rectangular or can have other shapes, such as polygonal or circular shapes for example.

Various embodiments of structures and methods were described herein. Structures and methods were variously described as transferring components 30, printing components 30, or micro-transferring components 30. In some embodiments, micro-transfer-printing involves using a transfer element 40 (e.g., an elastomeric stamp 40, such as a PDMS stamp 40) to transfer a component 30 using controlled adhesion. For example, an exemplary transfer device can use kinetic or shear-assisted control of adhesion between a transfer element and a component 30. It is contemplated that, in certain embodiments, where a method is described as including printing (e.g., micro-transfer-printing) a component 30, other similar embodiments exist using a different transfer method. In some embodiments, transferring or printing a component 30 (e.g., from a native component source substrate or wafer to a destination patterned target substrate 10) can be accomplished using any one or more of a variety of known techniques. For example, in certain embodiments, a pick-and-place method can be used to print components 30 or structures 20. As another example, in certain embodiments, a flip-chip method can be used (e.g., involving an intermediate, handle or carrier substrate). In methods according to certain embodiments, a vacuum tool, an electro-static tool, a magnetic tool, or other transfer device is used to transfer a component 30.

The figures that show transfer element 40 are simplified to show transfer element 40 printing a single component 30. In some embodiments, a single component 30 is printed using transfer element 40 in a single print step. Accordingly, 10 components 30 can be printed using transfer element 40 in 10 print steps. In some embodiments, a plurality of components are printed using transfer element 40 in a single print step. For example, in some embodiments, at least 10 components 30, e.g., at least 50 components 30, at least 100 components 30, at least 1,000 components 30, at least 10,000 components 30, or at least 50,000 components 30 can be or are printed in a single print step.

Those of ordinary skill in the art will appreciate that high-precision structures, components therefor, and methods of making that can be adapted into, applied to, and/or used with embodiments disclosed in the present application are disclosed in U.S. Pat. No. 10,714,374, the disclosure of which is hereby incorporated by reference in its entirety.

As is understood by those skilled in the art, the terms “over” and “under” are relative terms and can be interchanged in reference to different orientations of the layers, elements, and substrates included in various embodiments of the present disclosure. Furthermore, a first layer or first element “on” a second layer or second element, respectively, is a relative orientation of the first layer or first element to the second layer or second element, respectively, that does not preclude additional layers being disposed therebetween. For example, a first layer on a second layer, in some implementations, means a first layer directly on and in contact with a second layer. In other implementations, a first layer on a second layer includes a first layer and a second layer with another layer therebetween (e.g., and in mutual contact).

Having described certain implementations of embodiments, it will now become apparent to one of skill in the art that other implementations incorporating the concepts of the disclosure may be used. Therefore, the disclosure should not be limited to certain implementations, but rather should be limited only by the spirit and scope of the following claims.

Throughout the description, where apparatus and systems are described as having, including, or comprising specific elements, or where processes and methods are described as having, including, or comprising specific steps, it is contemplated that, additionally, there are apparatus and systems of the disclosed technology that consist essentially of, or consist of, the recited elements, and that there are processes and methods according to the disclosed technology that consist essentially of, or consist of, the recited processing steps.

It should be understood that the order of steps or order for performing certain action is immaterial so long as the disclosed technology remains operable. Moreover, two or more steps or actions in some circumstances can be conducted simultaneously. The disclosure has been described in detail with particular reference to certain embodiments thereof, but it will be understood that variations and modifications can be effected within the spirit and scope of the following claims.

### PARTS LIST

A cross section line
D distance
M movement direction
S separation distance
10 target substrate
11 surface/substrate surface/cavity bottom surface
12 optional adhesive/optional adhesive layer
13 top surface
14 substrate contact pad
15 cavity
16 gutter/trench
20 structure/alignment structure/substrate structure
20A first structure
20B second structure
22 gap
24 light pipe
25 reflector
26 indentation
28 component structure
30 component
30A first component
30B second component
31 connection post
32 tether/broken (e.g., fractured) or separated tether
34 micro-laser/micro-diode laser
36 protrusion
38 component substrate
40 stamp/transfer element
42 stamp post
50 lower light-reflective layer
52 upper light-reflective layer
60 light
70 integrated circuit
72 electrode
74 dielectric layer/encapsulation layer
76 photosensor
80A first component end
80B second component end
99 printed structure
100 provide substrate step
110 provide component source substrate step
115 provide source substrate with components having ends with non-parallel edges step
120 provide stamp step
130 pick up components with stamp step
140 form structures on substrate step
142 form structures with non-parallel edges on target substrate step
145 form gutters step
150 dispose adhesive step
160 print components onto substrate with stamp step
162 print components onto substrate in alignment with two or more structures with stamp step
164 push adhesive toward structures step
166 push adhesive between structures into gap step
168 push adhesive into gutter step
170 separate stamp step
180 optional cure adhesive step
200 press component toward target substrate step
210 separate stamp from component step
220 contact component to structure but not target substrate step
230 press component toward substrate with stamp step
240 contact component to substrate with stamp step
250 move stamp vertically away from substrate step
260 move stamp horizontally parallel to substrate step
270 move stamp horizontally parallel to substrate and vertically away from substrate step

1. A printed structure, comprising:
a target substrate and structures extending from a surface of the target substrate;
a component disposed on the surface in alignment with the structures, wherein the component is non-native to the target substrate.

2. The printed structure of claim 1, wherein the component is disposed on the surface of the target substrate within one micron of at least one of the structures, of two or more of the structures, or of all of the structures.

3. The printed structure of claim 1, comprising a cavity disposed within the target substrate, wherein the cavity comprises a cavity bottom and cavity walls, the surface of the target substrate is the cavity bottom, and at least one of the structures comprises one of the cavity walls.

4. The printed structure of claim 3, comprising multiple components each non-native to the target substrate and disposed in the cavity in alignment with groups of structures on the surface.

5. The printed structure of claim 1, wherein at least one of the structures is native to the target substrate.

6. The printed structure of claim 1, wherein at least one of the structures is non-native to the target substrate.

7-15. (canceled)

16. The printed structure of claim 1, wherein the structures comprise a first structure having a first structure edge and a second structure having a second structure edge, the component has a first component end having a first component edge and an opposing second component end having a second component edge, the first structure edge is at a non-orthogonal angle with respect to the second structure edge in a direction parallel to the surface, and the first component edge is substantially parallel to the first structure edge and the second component edge is substantially parallel to the second structure edge.

17. The printed structure of claim 1, comprising an adhesive disposed on the target substrate and wherein the component is disposed on the adhesive.

18. The printed structure of claim 1, wherein the component has a longer side and a shorter side, wherein the component is adjacent to more of the structures on the longer side than on the shorter side.

19-22. (canceled)

23. The printed structure of claim 1, wherein one or more of the structures are disposed on a first side of the component and one or more of the structures are disposed on a second side of the component different from the first side.

24. The printed structure of claim 1, wherein the component comprises a broken or separated tether that is disposed laterally between ones of the structures.

25. The printed structure of claim 1, wherein each of the structures comprises an edge and the component is disposed adjacent to the structures such that a gap exists between each of the edges and the component.

26. The printed structure of claim 25, comprising an adhesive disposed on the target substrate, wherein the component is disposed on the adhesive and the adhesive is disposed between the component and the surface of the target substrate.

27. The printed structure of claim 26, wherein the adhesive is also disposed in the gap and has a thickness in the gap that is greater than a thickness of the adhesive between the component and the surface of the target substrate.

28. The printed structure of claim 26, wherein the adhesive is also disposed in the gap and has a thickness in the gap that is greater than a thickness of the adhesive between the edges of two or more of the structures.

29. The printed structure of claim 25, wherein the component has a cut-off corner that defines the gap between the component and each of the edges.

30. The printed structure of claim 1, comprising a gutter formed in the target substrate and disposed between the component and at least one of the structures, beneath the component, or both between the component and at least one of the structures and beneath the component.

31. The printed structure of claim 30, comprising an adhesive that adheres the component to the target substrate, wherein the gutter is at least partially filled with the adhesive.

32. The printed structure of claim 30, wherein the adhesive is disposed on the surface between the component and the surface.

33. The printed structure of claim 30, wherein (i) the gutter has a depth no less than 500 nm, (ii) the gutter has a depth no less than a thickness of the adhesive between the component and the surface, or (iii) both (i) and (ii).

34-73. (canceled)
